(19) United States
(12) Patent Application Publication
(10) Pub. No.: US 2025/0126804 A1
(43) Pub. Date: Apr. 17, 2025

(54) MEMORY CELL ARRANGEMENT AND METHODS

(71) Applicant: Ferroelectric Memory GmbH, Dresden (DE)

(72) Inventors: Bart Vermeulen, Dresden (DE); Stefan Müller, Radebeul (DE); Tony Schenk, Dresden (DE); Dina H. Triyoso, Albany, NY (US); Kandabara Tapily, Albany, NY (US); Robert Clark, Livermore, CA (US)

(21) Appl. No.: 18/486,180

(22) Filed: Oct. 13, 2023

(51) Int. Cl. H10B 53/30

(52) U.S. Cl. CPC H10B 53/30

(57) ABSTRACT

A memory cell arrangement and methods are disclosed, wherein the memory cell arrangement includes: a substrate including a plurality of three-dimensional structures; a plurality of memory cells; and a plurality of sets of control lines for selectively addressing the plurality of memory cells, wherein each memory cell includes a respective one of the plurality of three-dimensional structures and a memory layer stack disposed over the three-dimensional structure, the memory layer stack including a first electrode, a second electrode, and a memory element forming a memory capacitor; wherein the memory element substantially consists of one or more transition-metal-oxides, wherein the second electrode includes an electrically conductive electrode layer substantially consisting of tungsten and a functional layer substantially consisting of a metal nitride or a metal-oxynitride, wherein the functional layer is disposed between the memory element and the electrically conductive electrode layer and in direct contact with the memory element.

### TECHNICAL FIELD

Various aspects relate to a memory cells, memory cell arrangements, and methods, such as a method for manufacturing a memory cell and/or a memory cell arrangement.

### BACKGROUND

In general, various computer memory technologies have been developed in semiconductor industry. A fundamental building block of a computer memory may be referred to as memory cell. The memory cell may be an electronic circuit that is configured to store at least one information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a type of memory cell may include a thin film of a spontaneous-polarizable material, e.g., a ferroelectric material or a configuration of an anti-ferroelectric material, whose polarization state may be changed in a controlled fashion to store data in the memory cell, e.g., in a non-volatile manner. A memory cell or an arrangement of memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1A to FIG. 1C each show various aspects of a capacitive memory structure in a schematic view;

FIG. 1D to FIG. 1G each show a memory cell arrangement according to various aspects;

FIG. 2A shows a spontaneously polarizable capacitor structure conformally covering a trench according to various aspects;

FIG. 2B to FIG. 2H each show at least one spontaneously polarizable capacitor structure conformally covering a three-dimensional structure according to various aspects;

FIG. 3A to FIG. 3F, FIG. 5, FIG. 7 each show an exemplary configuration of a spontaneously polarizable capacitor structure according to various aspects;

FIG. 4A shows a flow diagram of a method of manufacturing a memory cell according to various aspects;

FIG. 4B shows a flow diagram of a method of manufacturing a memory cell arrangement according to various aspects;

FIG. 6A shows a flow diagram of a method of manufacturing a memory cell according to various aspects and FIG. 6B shows exemplary configurations of the memory cell during the manufacturing; and

FIG. 8A shows a flow diagram of a method for generating a metal layer on an oxide layer according to various aspects and FIG. 8B shows exemplary configurations of the memory cell during the generation of the metal layer.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

In the semiconductor industry, the integration of non-volatile memory technologies, sensor technologies, transmitter technologies, electronic filter technologies, receiver technologies, and the like may be useful for various types of devices and applications. According to various aspects, an electronic device, e.g., a non-volatile memory may be integrated on a chip.

It has been found that depositing a metal over an oxide layer using atomic layer deposition (ALD) results in a damaging (e.g., etching) of a surface of the oxide layer. In various scenarios, this may lead to reduced electronic properties of electronic devices, such as memory cells, having such a metal layer disposed on the oxide layer. In some cases, the deposition of the metal may result in an electrode layer on the oxide layer, but having low electric properties. In other cases (such as in the case of depositing tungsten), the metal does not adhere on the surface of the oxide layer such that no metal electrode layer can be formed by ALD. In an experimental investigation a memory element layer having a thickness of about 10 nm and substantially consisting of hafnium zirconium oxide (HZO) was formed using ALD and subsequently an ALD of tungsten (as metal) was carried out (with the number of ALD cycles corresponding to about 10 nm of tungsten). It has been found that a surface layer of the memory element layer is etched and that no tungsten layer is deposited on the memory element layer.

However, in some scenarios, e.g., in the case that a layer is to be deposited conformally over a three-dimensional structure having an aspect ratio above a threshold value, it may be required to use ALD.

Various aspects relate to methods which allow to deposit a metal electrode layer (e.g., substantially consisting of tungsten) over an oxide layer using ALD. Further, the methods allow to form a capacitive memory structure having improved electronic properties (e.g., due to interfaces with less damage resulting from ALD of the metal). According to some aspects, a metal nitride layer is deposited over the oxide layer and the metal electrode layer is deposited directly on the metal nitride layer using ALD. Hence, the metal nitride layer may serve as a nucleation layer (also referred to as seed layer) for the metal electrode layer. According to other aspects, a metal-oxynitride layer is deposited over the oxide layer and the metal electrode layer is deposited directly on the metal nitride layer using ALD. Hence, the metal-oxynitride layer may serve as a nucleation layer for the metal electrode layer. According to even other aspects, a metal nitride layer is deposited over the oxide layer and the metal nitride layer is then oxidized and subsequently reduced to the metal. Various aspects relate to devices (e.g., memory cells and/or memory cells) manufactured using one of the methods. Such a device may have a three-dimensional structure (e.g., a trench) requiring ALD for conformally forming at least one metal layer.

An example of such a device is a memory cell which has a memory element that substantially consists of a (e.g., spontaneously polarizable) oxide material (e.g., of one or more transition-metal-oxides). In the following, various aspects are described exemplarily for such a memory cell. However, it is understood that the principles described herein are applicable to any kind device having a metal layer disposed over an oxide layer. For example, the principles described herein are applicable to any kind of device having a metal electrode layer over an oxide layer.

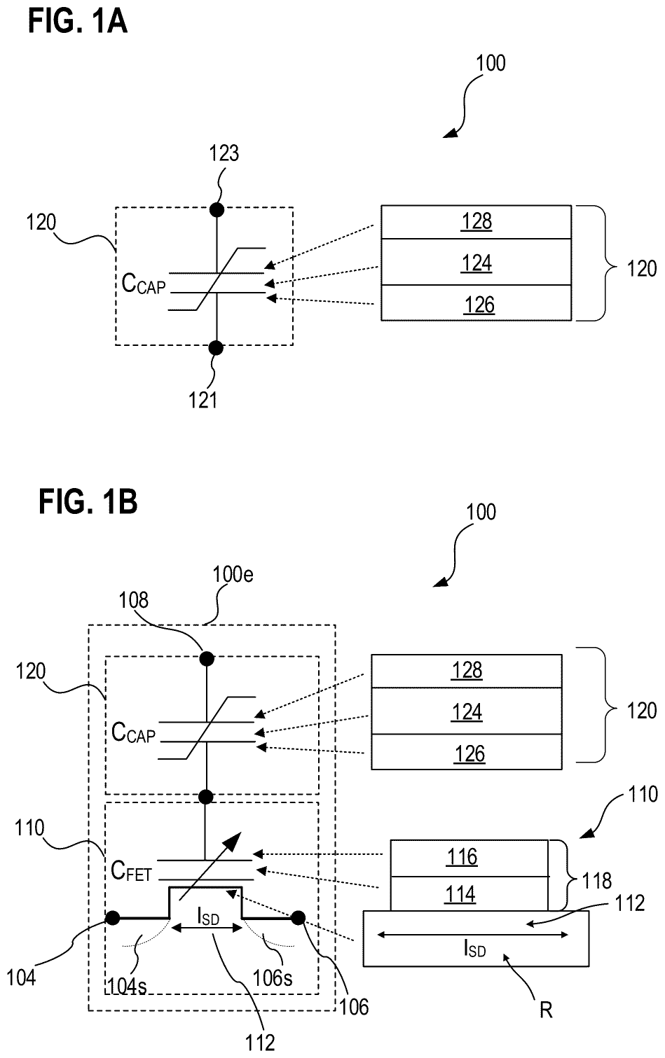

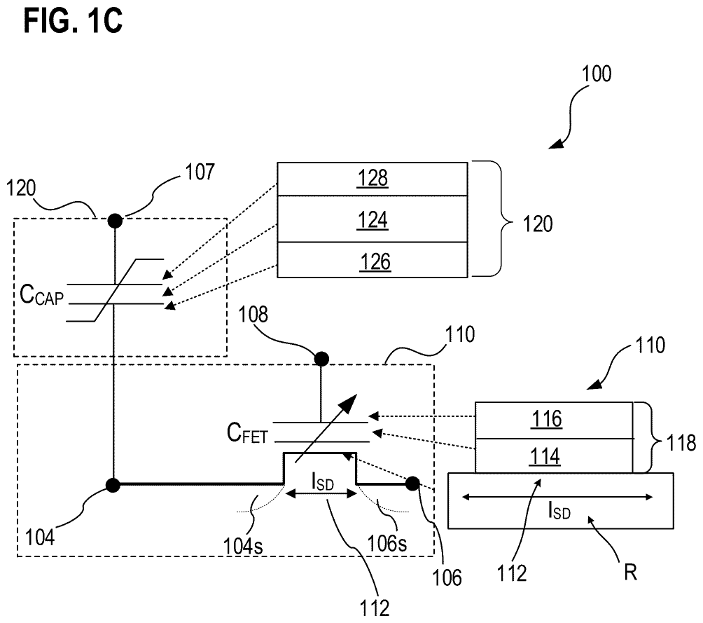

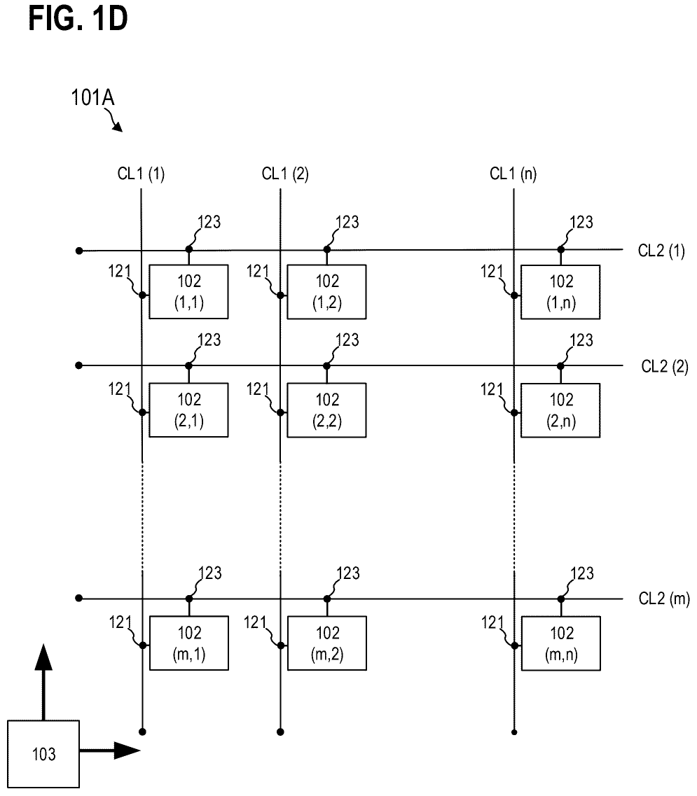

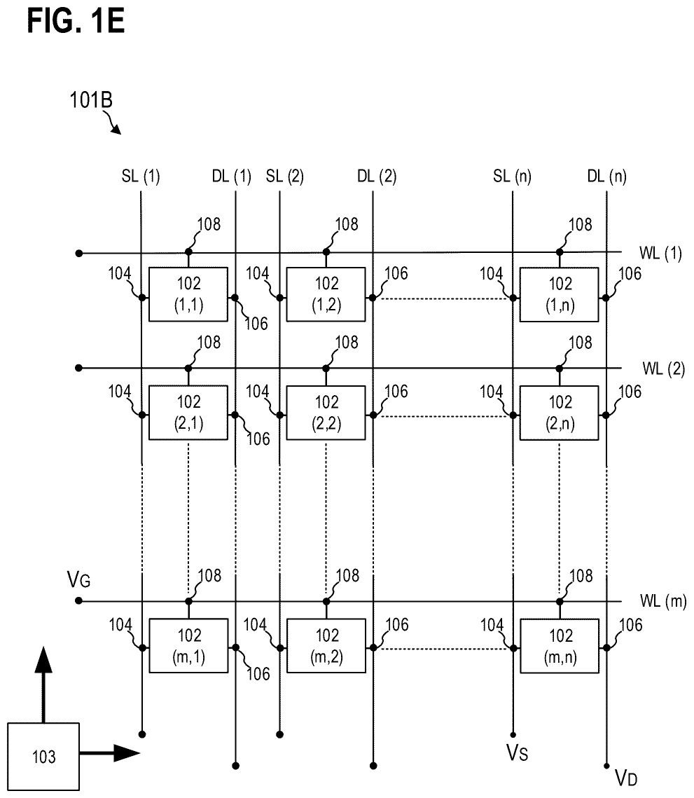

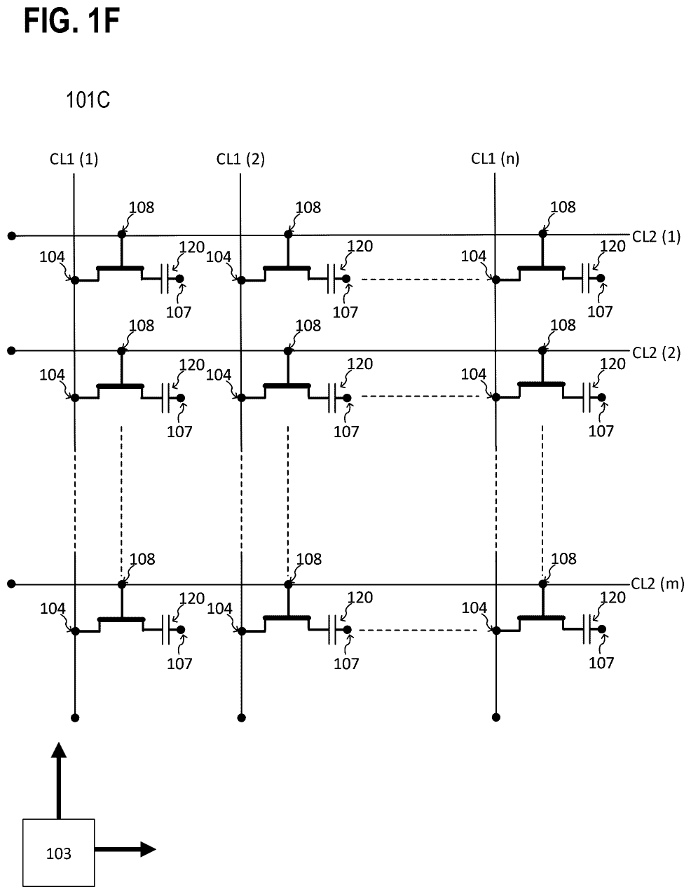

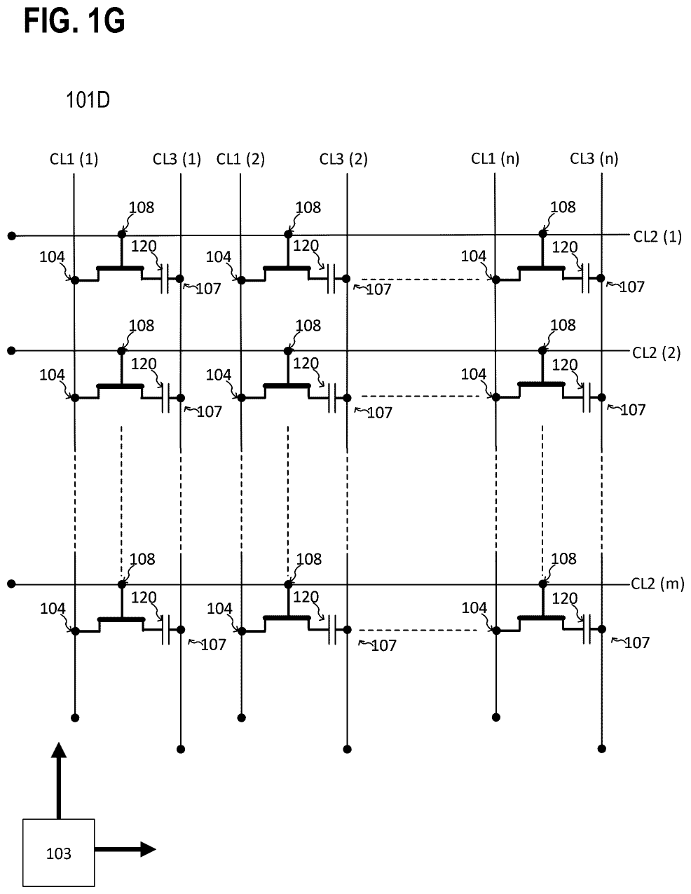

FIG. 1A shows various aspects of a memory structure 100. The memory structure 100 may include a capacitive memory structure, such as a spontaneously polarizable capacitor, SPOC, structure 120. The SPOC structure 120 (in some aspects also referred to as memory layer stack) may include at least two electrodes (e.g., two electrode layers), such as a first electrode 126 and a second electrode 128. The SPOC structure 120 may include a memory element 124. The memory element 124 may be disposed between the first electrode 126 and the second electrode 128. The memory element 124 may be disposed in direct physical contact with the first electrode 126 and in direct physical contact with the second electrode 128. The memory element 124 may include or may consist of a spontaneously polarizable material. A memory element including or consisting of a spontaneously polarizable material may also be referred to as spontaneously-polarizable memory element 124. For example, the spontaneously polarizable material may be a remanent polarizable material, such as a ferroelectric material, or a non-remanent polarizable material, such as an anti-ferroelectric material. A memory element including or consisting of a spontaneously polarizable material may be understood such that the memory element has (e.g., within the framework of the SPOC structure 120) spontaneously polarizable properties. According to various aspects, the first electrode 126, the second electrode 128, and the memory element 124 may form the SPOC structure 120. The SPOC structure 120 may, in some aspects, also be referred to as memory capacitor.

The SPOC structure 120 may be part of or may form a memory cell 102. The first electrode 126 may be coupled to a first terminal 121 and the second electrode 128 may be coupled to a second terminal 123. Thus, in this scenario, the memory cell 102 may be a two-terminal memory cell.

The spontaneously-polarizable memory element 124 may show a hysteresis in the (voltage (drop) dependent) polarization. The spontaneously-polarizable memory element 124 may show non-remanent spontaneous polarization (e.g., may show anti-ferroelectric properties), e.g., the spontaneously-polarizable memory element may have no or no substantial remanent polarization remaining in the case that no voltage drops over the spontaneously-polarizable memory element 124. In other aspects, the spontaneously-polarizable memory element 124 may show remanent spontaneous polarization (e.g., may show ferroelectric properties), e.g., the spontaneously-polarizable memory element 124 may have a remanent polarization or a substantial remanent polarization remaining in the case that no voltage drops over the spontaneously-polarizable memory element.

The terms “spontaneously polarized” or “spontaneous polarization” may be used herein, for example, with reference to the polarization capability of a material beyond dielectric polarization. A “spontaneously-polarizable” (or “spontaneous-polarizable”) material may be or may include a spontaneously-polarizable material that shows a remanence, e.g., a ferroelectric material, and/or a spontaneously-polarizable material that shows no remanence, e.g., an anti-ferroelectric material. The coercivity of the spontaneously-polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C—V) and/or time-resolved measurement or by polarization-voltage (P—V) or positive-up-negative-down (PUND) measurements.

According to various aspects, in various types of applications, e.g., in memory technology, a remanent polarization as low as 0 μC/cm² to 3 μC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 μC/cm² may be regarded as substantial remanent polarization. Such a substantial remanent polarization may allow for storing information as a function of a polarization state of a spontaneously polarizable layer or a spontaneously polarizable material.

In a usual capacitor structure, the amount of charge stored therein may be used to define a memory state (e.g., first amount of charge stored in the capacitor structure may define a first memory state and a second amount of charge stored in the capacitor structure may define a second memory state.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, E_{C}, (also referred to as coercive field) may be or may represent the electric field required to depolarize a remanent-polarizable layer.

According to various aspects, the spontaneously-polarizable memory element 124 may include or may consist of a remanent-polarizable material. A remanent-polarizable material may be a material that is remanently polarizable and shows a remanence of the spontaneous polarization, such as a ferroelectric material. In other aspects, remanent-polarizable material may be a material that is spontaneously polarizable and that shows no remanence, e.g., an anti-ferroelectric material under the additional conditions that measures are implemented to generate an internal electric-field within the anti-ferroelectric material. Hence, a non-remanently polarizable material, such as an anti-ferroelectric (“antiferroelectric”) material may exhibit remanent polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element 124, thereby establishing the spontaneously polarizable properties, only as examples. The spontaneously-polarizable memory element 124 including or being made of a remanent-polarizable material may be referred to herein as remanent-polarizable memory element (e.g., as remanent-polarizable layer).

In some aspects, the spontaneous-polarizable material (e.g., a remanent-polarizable material) may be based on at least one metal oxide. Illustratively, a composition of the spontaneous-polarizable material may include the at least one metal oxide for more than 50%, or more than 66%, or more than 75%, or more than 90%. In some aspects, the spontaneous-polarizable material may include one or more metal oxides. The spontaneous-polarizable material may include (or may be based on) at least one of HfₐO_{b}, ZrₐO_{b}, SiₐO_{b}, YₐO_{b}, as examples, wherein the subscripts “a” and “b” may indicate the number of the respective atom in the spontaneous-polarizable material.

In some aspects, the spontaneous-polarizable material (e.g., the remanent-polarizable material) may be or may include a ferroelectric material, illustratively the memory element 124 may be ferroelectric memory element (for example a ferroelectric layer). A ferroelectric material may be an example of a material used in a spontaneously-polarizable memory element (e.g., in a remanent-polarizable element). The ferroelectric material may be or may include at least one of the following: hafnium oxide (ferroelectric hafnium oxide, HfO₂), zirconium oxide (ferroelectric zirconium oxide, ZrO₂), a (ferroelectric) mixture of hafnium oxide and zirconium oxide (also referred to as hafnium zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g., but not limited to it, a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 2 mol % to about 6 mol %, only as an example.

In some aspects, the spontaneous-polarizable material may include hafnium oxide (e.g., may consist of hafnium oxide, hafnium zirconium oxide (e.g., Hf_{0.75} Zr_{0.25} O₂ or Hf_{0.5} Zr_{0.5} O₂), hafnium silicon oxide, hafnium lanthanum oxide, or hafnium lanthanum zirconium oxide), zirconium oxide, and/or aluminum nitride (e.g., may consist of aluminum nitride, aluminum scandium nitride or aluminum boron nitride). In some aspects, the spontaneous-polarizable material may include or may consist of Hf₁₋ₓZrₓO₂, Hf₁₋ₓSiₓO₂, Hf₁₋ₓLaₓO₂, Hf_{1-x-y} LaₓZr_{y}O₂, Al₁₋ₓScₓN, or Al₁₋ₓBₓN.

The spontaneously polarizable material of the memory element 124 may include or may consist of lead zirconate titanate (Pb[ZrₓTi₁₋ₓ]O₃, PZT) or strontium bismuth tantalate (Sr₂Bi_{z}TaO₉, SBT). However, there are several disadvantages for integrating PCT and SBT in complementary metal-oxide-semiconductor (CMOS):
Polycrystalline PZT or SBT films may require a thickness of more than 70 nm in order to ensure that the complete film is ferroelectric. However, the lateral dimension in CMOS integration may not be scalable such that the thick films lead to huge height difference between the SPOC structure 120 and the logic area forming below the interlayer metallization.
PZT and SBT require four elements and cannot be deposited using atomic layer deposition (ALD). Hence, PZT and SBT cannot be used for a 3D-integration of the SPOC structure 120, but merely for planar structures.
PZT and SBT include elements which may contaminate CMOS facilities. PZT even includes lead (Pb) which is considered toxic. This may require a special encapsulation of the whole SPOC structure 120. Further, dedicated tools may be required for depositing the toxic elements.
PZT and SBT have a comparatively small band gap (e.g., 3.0 to 3.5 eV for PZT). Hence, PZT and SBT cannot be used for devices that require low leakage currents through the SPOC structure 120.

As described, the spontaneously polarizable material of the memory element 124 may consist of hafnium zirconium oxide (Hf₁₋ₓZrₓO₂, HZO) with 0≤x≤1 (i.e., consisting of hafnium oxide in the case of x=0 and consisting of zirconium oxide in the case of x=1). There are several advantages of HZO for CMOS integration:
HZO films are ferroelectric or antiferroelectric down to a thickness of 1 nm. Hence, the integration of the SPOC structure 120 in lateral dimension is scalable to a maximum degree.
HZO films can be deposited using ALD. This allows to manufacture SPOC structure 120 having curved structures and allow a 3D-integration of the SPOC structure 120.
HZO films are CMOS compatible and do not include any toxic elements. Hence, an encapsulation of the SPOC structure 120 may be optional and the standard CMOS equipment can be used.
It may be possible to crystallize the HZO into the ferroelectric phase by annealing at temperatures in a range from about 300° C. to about 400° C. This allows an integration of the SPOC structure 120 as part of the interlayer metallization.
HZO films have a large band gap (e.g., 5.8 eV for hafnium oxide). Thus, HZO can be used for devices that require a low leakage current.

According to various aspects, the memory capacitor as provided by the SPOC structure 120 may be or may include a ferroelectric capacitor (FeCAP) or an anti-ferroelectric capacitor (AFeCAP). An information may be stored by the memory capacitor via at least two remanent polarization states of the SPOC structure 120. The programming of the SPOC structure 120 (illustratively the storage of information therein) may be carried out by providing (e.g., applying) an electric field to thereby set or change the remanent polarization state of the spontaneously polarizable memory element 124. Illustratively, the spontaneous-polarizable material (e.g., a ferroelectric material, e.g., an anti-ferroelectric material) may be used to store data in non-volatile manner in integrated circuits.

The spontaneously polarizable may include (e.g., may substantially consist of) an oxide (e.g., a first oxide) of a first transition metal (in some aspects referred to as first transition-metal-oxide) and an oxide (e.g., a second oxide) of a second transition metal (in some aspects referred to as second transition-metal-oxide). The phrase that a layer may include (e.g., substantially consists of) more than one transition-metal-oxide may be understood to mean that the layer includes (e.g., substantially consists of) a mixed material of the (first) oxide of the first transition metal and the (second) oxide of the second transition metal. An example of the mixed material of the (first) oxide of the first transition metal and the (second) oxide of the second transition metal may be Hf₁₋ₓZrₓO₂, HZO) with 0<x<1. A mixed material of the (first) oxide of the first transition metal and the (second) oxide of the second transition metal may be understood to mean a material mixture substantially consisting the (first) oxide of the first transition metal and the (second) oxide of the second transition metal.

It may be understood that, even though various aspects refer to a memory element including or being made of a spontaneously-polarizable material, other memory elements whose state may be altered by an electric field provided across a capacitive memory structure may be used as long as the structure of the material can be changed via application of an electric field, as described herein.

The SPOC structure 120 may have a capacitive configuration with a (first) capacitance, C_{CAP}, associated therewith (see equivalent circuit 100e in FIG. 1A with respect to the capacitive properties). The first electrode 126, the memory element 124, and the second electrode 128 may form a memory capacitor layer stack. In some aspects, the memory capacitor layer stack may be a planar layer stack; however, other shapes may be suitable as well, e.g., curved shapes, angled shapes, coaxially aligned shapes, as examples. Illustratively, the SPOC structure 120 may include planar electrodes, or, in other aspects, the SPOC structure 120 may be configured as 3D capacitor including, for example, angled or curved electrodes.

With reference to FIG. 1B, the memory structure 100 may be a field-effect transistor (FET) based capacitive memory structure. The memory structure 100 may include a field-effect transistor structure 110 and the capacitive memory structure (e.g., the SPOC structure 120). The SPOC structure 120 may be coupled to the field-effect transistor structure 110. The field-effect transistor structure 110 may include a gate structure 118, wherein the gate structure 118 may include a gate isolation 114 and a gate electrode 116. The gate structure 118 is illustrated exemplarily as a planar gate stack; however, it is understood that the planar configurations shown in FIG. 1A and FIG. 1B are examples, and that other field-effect transistor designs may include a gate structure 118 with a non-planar shape, for example a trench gate transistor design, a vertical field-effect transistor design, or other designs, such as a fin-FET design.

In this scenario, the memory cell 102 may be a three-terminal memory cell. Thus, the memory cell 102 may have a first terminal 104 (e.g., a source terminal), a second terminal 106 (e.g., a drain terminal), and a third terminal 108 (e.g., a gate terminal). The memory cell 102 may include a field-effect transistor structure 110. The field-effect transistor structure 110 may include a first source/drain region 104s (e.g., a source region). The first source/drain region 104s may be connected to the first terminal 104 of the memory cell 102. The field-effect transistor structure 110 may include a second source/drain region 106s (e.g., a drain region). The second source/drain region 106s may be connected to the second terminal 106 of the memory cell 102. The field-effect transistor structure 110 may include the gate structure 108g (e.g., a gate region). The gate structure 108g may be connected to the third terminal 108 of the memory cell 102.

The gate structure 118 may define a channel region 112, e.g., provided in a semiconductor portion (e.g., in a semiconductor layer, in a semiconductor die, etc.). The gate structure 118 may allow for a control of an electrical behavior (e.g., a resistance R) of the channel region 112, e.g., a current flow in the channel region 112 may be controlled (e.g., allowed, increased, prevented, decreased, etc.). In some aspects, the gate structure 118 may, for example, allow to control (e.g., allow or prevent) a source/drain current, I_{SD}, from a first source/drain region of the field-effect transistor structure 110 to a second source/drain region of the field-effect transistor structure 110 (the source/drains are provided in or adjacent to the channel but are not shown in FIG. 1B). The channel region 112 and the source/drain regions may be formed, e.g., via doping one or more semiconductor materials or by the use of intrinsically doped semiconductor materials, within a layer and/or over a layer. With respect to the operation of the field-effect transistor structure 110, a voltage may be provided at the gate electrode 116 to control the current flow, I_{SD}, in the channel region 112, the current flow, I_{SD}, in the channel region 112 being caused by voltages supplied via the source/drain regions.

According to various aspects, the semiconductor portion (illustratively, where the channel region 112 may be formed), may be made of or may include silicon. However, other semiconductor materials of various types may be used in a similar way, e.g., germanium, Group III to V (e.g., SiC), or other types, including for example carbon nanotubes, organic materials (e.g., organic polymers), etc. In various aspects, the semiconductor portion may be a wafer made of silicon (e.g., p-type doped or n-type doped). In other aspects, the semiconductor portion may be a silicon on insulator (SOI) wafer. In other aspects, the semiconductor portion may be provided by a semiconductor structure, e.g., by one or more semiconductor fins, one or more semiconductor nanosheets, one or more semiconductor nanowires, etc., disposed at a carrier.

The gate electrode 116 may include an electrically conductive material, for example, a metal, a metal alloy, a degenerate semiconductor (in other words a semiconductor material having such a high level of doping that the material acts like a metal and not anymore as a semiconductor), and/or the like. As an example, the gate electrode 116 may include or may be made of aluminum. As another example, the gate electrode 116 may include or may be made of polysilicon. According to various aspects, the gate electrode 116 may include one or more electrically conductive portions, layers, etc. The gate electrode 116 may include, for example, one or more metal layers (also referred to as a metal gate), one or more polysilicon layers (also referred to as poly-Si-gate), etc. A metal gate may include, for example, at least one work-function adaption metal layer disposed over the gate isolation 114 and an additional metal layer disposed over the work-function adaption metal layer. A poly-Si-gate may be, for example, p-type doped or n-type doped.

The gate isolation 114 may be configured to provide an electrical separation of the gate electrode 116 from the channel region 112 and further to influence the channel region 112 via an electric field generated by the gate electrode 116. The gate isolation 114 may include one or more electrically insulating layers, as an example. Some designs of the gate isolation 114 may include at least two layers including different materials, e.g., a first gate isolation layer (e.g., a first dielectric layer including a first dielectric material) and a second gate isolation layer (e.g., a second dielectric layer including a second dielectric material distinct from first dielectric material).

As illustrated by the circuit equivalent in FIG. 1B, a (second) capacitance, C_{FET}, may be associated with the field-effect transistor structure 110. Illustratively, the channel region 112, the gate isolation 114, and the gate electrode 116 may have a capacitance, C_{FET}, associated therewith, originating from the more or less conductive regions (the channel region 112 and the gate electrode 116) separated from one another by the gate isolation 114. Further illustratively, the channel region 112 may be considered as a first capacitor electrode, the gate electrode 116 as a second capacitor electrode, and the gate isolation 114 as a dielectric medium between the two capacitor electrodes. The capacitance, C_{FET}, of the field-effect transistor structure 110 may define one or more operating properties of the field-effect transistor structure 110. The configuration of the field-effect transistor structure 110 (e.g., of the gate isolation 114) may be adapted according to a desired behavior or application of the field-effect transistor structure 110 during operation (e.g., according to a desired capacitance).

In general, the capacitance, C, of a planar capacitor structure may be expressed as,

$$C = {ε}_{0} {ε}_{r} \frac{A}{d} ,$$

with ε₀ being the relative permittivity of the vacuum, A being the effective area of the capacitor, d being the distance of the two capacitor electrodes from one another, and εᵣ being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art.

In some aspects, the gate electrode 116 of the field-effect transistor structure 110 and the first electrode 126 of the SPOC structure 120 that is connected to the field-effect transistor structure 110 may be spatially separated from one another and electrically connected via a conductive connection, e.g., one or more metal lines. In other aspects, the gate electrode 116 of the field-effect transistor structure 110 and the first electrode 126 of the SPOC structure 120 may be in direct physical contact with one another or implemented as a single (shared) electrode. For example, an electrode layer may (as single (shared) electrode) provide both, the gate electrode 116 of the field-effect transistor structure 110 and the first electrode 126 of the SPOC structure 120.

The field-effect transistor structure 110 and the SPOC structure 120 form together a field-effect transistor based (e.g., capacitive) memory structure, as exemplarily shown in FIG. 1B. The gate 108 of the field-effect transistor based (e.g., capacitive) memory structure may be provided by the second electrode 128 or an additional electrode coupled to the second electrode 128.

According to various aspects, the memory structure 100 may provide or may be part of a memory cell. A memory cell may be provided, for example, by coupling a gate of a field-effect transistor structure with a (e.g., spontaneously polarizable) capacitive memory structure, or by integrating a memory structure in the gate structure of a field-effect transistor structure (as shown, in FIG. 1B for the field-effect transistor structure 110 and the SPOC structure 120). A memory cell may illustratively include a field-effect transistor structure and a SPOC structure coupled to or integrated in the field-effect transistor structure (optionally with one or more additional elements). In such a configuration the capacitive memory element) may be in a capacitive environment, e.g., disposed between two electrode layers or disposed between a channel of a field-effect transistor and an electrode layer (e.g., a gate electrode of the field-effect transistor). In such a memory cell, the state (e.g., the polarization state) of the memory element influences the threshold voltage of the field-effect transistor structure (e.g., a first state of the memory element may be associated with a first threshold voltage, such as a low threshold voltage, and a second state of the memory element may be associated with a second threshold voltage, such as a high threshold voltage). A memory cell that includes a field-effect transistor structure and a SPOC structure may be referred to as field-effect transistor based memory cell or field-effect transistor based capacitive memory cell. It is noted that even though various aspects of a memory cell are described herein with reference to a field-effect transistor based capacitive memory structure (such as a FeFET), other memory structures may be suitable as well.

The field-effect transistor structure 110 and the SPOC structure 120 may be coupled (e.g., electrically connected) to one another such that a capacitive voltage divider is provided. The capacitive voltage divider formed by the field-effect transistor structure 110 and the SPOC structure 120 may allow adapting the capacitances C_{FET}, C_{CAP} of the respective capacitors to allow an efficient programming of the memory cell. The overall gate voltage required for switching the memory cell from one memory state into another memory state (e.g., from high threshold voltage state to low threshold voltage state, as described below), may become smaller in case the voltage distribution across the field-effect transistor structure 110 and the SPOC structure 120 is adapted such that more of the applied gate voltage drops across the memory layer of the SPOC structure 120 (e.g., across the memory element 124) than across the gate isolation of the field-effect transistor structure 110. The overall write voltage (illustratively, applied via nodes to which the field-effect transistor structure 110 and the SPOC structure 120 are connected) may thus be reduced by adapting the capacitive voltage divider. The voltage distribution may be determined by voltage divider calculations for a series connection of the capacitors.

That is, in the case that the capacitance, C_{FET}, of the field-effect transistor structure 110 is adapted (e.g., by providing a suitable gate isolation) a predefined fraction of the voltage applied to the series connection may drop across the SPOC structure 120. Accordingly, the electric field generated across the gate isolation of the field-effect transistor structure 110 underneath the SPOC structure 120 could be reduced if desired. This may lead to a reduced interfacial field stress, which may lead to a reduced wear out of the interface due to, for example, charge injection. Therefore, the reduced electric field generated across the gate isolation may lead to improved endurance characteristics of the memory cell, that is, to an increased amount of possible state reversals until the memory cell may lose or change its memory properties.

By increasing the capacitance C_{FET} of the field-effect transistor structure 110 (e.g., by providing a gate isolation including a relatively thick layer of material with high dielectric constant), the depolarization field, E_{Dep}, of the spontaneously polarizable material of the memory element 124 may be reduced. The depolarization field may be expressed by the following set of equations, wherein the indices “FET” refer to the capacitor provided by the field-effect transistor structure 110 and the indices “CAP” refer to the capacitor provided by the SPOC structure 120, as described herein:

$${V}_{F E T} + {V}_{C A P} = 0 ,$$

$$D = {ε}_{0} {ε}_{F E T} {E}_{F E T} = {ε}_{0} {ε}_{C A P} {E}_{C A P} + P ,$$

$${E}_{C A P} ≡ {E}_{D e p} = - {P ( {ε}_{0} {ε}_{C A P} ( \frac{{C}_{F E T}}{{C}_{C A P}} + 1 ) )}^{- 1} .$$

The depolarization field E_{Dep} may be detrimental to data retention since, depending on its magnitude, it may depolarize the remanent-polarizable layer. However, the magnitude may be reduced by increasing the capacitance ratio C_{FET}/C_{CAP}. Accordingly, in case the capacitance C_{FET} of the field-effect transistor structure 110 is increased, the depolarization field is reduced. This in turn improves the data retention of the memory cell.

According to various aspects, a threshold voltage of a field-effect transistor structure (and in a corresponding manner the threshold voltage of a field-effect transistor based memory cell) may be defined as a constant current threshold voltage (referred to as V_{th(ci)}). In this case, the constant current threshold voltage, V_{th(ci)}, may be a determined gate source voltage, V_{GS}, at which the drain current (referred to as I_{D}) is equal to a predefined (constant) current. The predefined (constant) current may be a reference current (referred to as I_{D0}) times the ratio of gate width (W) to gate length (L). The magnitude of the reference current, I_{D0}, may be selected to be appropriate for a given technology, e.g., 0.1 μA. In some aspects, the constant current threshold voltage, V_{th(ci)}, may be determined based on the following equation:

$${V}_{t h ( c i )} = {V}_{G S} ( at {I}_{D} = {I}_{D 0} \cdot W / L ) .$$

A threshold voltage of a field-effect transistor structure (e.g., of the field-effect transistor structure 110) may be defined by the properties of the field-effect transistor structure (e.g., the materials, the doping, etc.), and it may thus be a (e.g., intrinsic) property of the field-effect transistor structure.

According to various aspects, a memory cell may be addressed via a corresponding access device. An access device may include or may be, for example, a field effect transistor (FET), such as an n-type or p-type field-effect transistor, a transmission gate, such as an n-type-based or p-type-based transmission gate, or the like. An access device may have a threshold voltage associated therewith. A threshold voltage of an access device (e.g., a field-effect transistor) may be defined by the properties of the access device (e.g., the field-effect transistor), such as the material(s), the doping(s), etc., and it may thus be a (e.g., intrinsic) property of the access device.

According to various aspects, a memory cell may have at least two distinct memory states associated therewith, for example with two distinct electrical conductivities or two distinct amounts of stored charge that may be determined to determine in which of the at least two distinct states the memory cell is residing in. A memory cell including a field-effect transistor structure may include a first memory state, for example associated with a low threshold voltage state (referred to as LVT associated with the LVT memory state), and a second memory state, for example associated with a high threshold voltage state (referred to as HVT state associated with the HVT memory state). The high threshold voltage state may be, in some aspects, associated with a lower current flow during readout than the low threshold voltage state. The low threshold voltage state may be an electrically conducting state (e.g., associated with a logic memory state “1”, also referred to as a memory state or programmed state) and the high threshold voltage state may be an electrically non conducting state or at least less conducting than the low threshold voltage state (e.g., associated with a logic memory state “0”, also referred to as a memory state or erased state). However, the definition of the LVT state and the HVT state and/or the definition of a logic “0” and a logic “1” and/or the definition of “programmed state” and “erased state” may be selected arbitrarily. Illustratively, the first memory state may be associated with a first threshold voltage of the FET based memory cell, and the second memory state may be associated with a second threshold voltage of the FET based memory cell. However, the definition of the memory states and/or the definition of a logic “0” and a logic “1” may be selected arbitrarily.

According to various aspects, the residual polarization of the memory element 124 (e.g., the polarization of the spontaneously-polarizable material of the memory element 124) may define the memory state a memory cell is residing in. According to various aspects, a memory cell may reside in a first memory state in the case that the memory element is in a first polarization state, and the memory cell may reside in a second memory state in the case that the memory element is in a second polarization state (e.g., opposite to the first polarization state). As an example, the polarization state of the memory element may determine the amount of charge stored in the SPOC structure 120. The amount of charge stored in the SPOC structure 120 may be used to define a memory state of the memory cell. The threshold voltage of a field-effect transistor structure may be a function of the polarization state of the memory element 124, e.g., may be a function of the amount and/or polarity of charge stored in the SPOC structure 120. A first threshold voltage, e.g., a low threshold voltage V_{L-th}, may be associated with the first polarization state (e.g., with the first amount and/or polarity of stored charge), and a second threshold voltage, e.g., a high threshold voltage V_{H-th}, may be associated with the second polarization state (e.g., with the second amount and/or polarity of stored charge). A current flow from nodes to which the field-effect transistor structure and the SPOC structure 120 are coupled may be used to determine the memory state in which the memory cell is residing in.

According to various aspects, writing a memory cell or performing a write operation of a memory cell may include an operation or a process that modifies the memory state the memory cell is residing in from a (e.g., first) memory state to another (e.g., second) memory state. According to various aspects, writing a memory cell may include programming a memory cell (e.g., performing a programming operation of a memory cell), wherein the memory state the memory cell is residing in after programming may be called “programmed state”. For example, programming an n-type FET based memory cell may modify the state the memory cell is residing in from the HVT state to the LVT state, whereas programming a p-type FET based memory cell may modify the state the memory cell is residing in from the LVT state to the HVT state. According to various aspects, writing a memory cell may include erasing a memory cell (e.g., performing an erasing operation of a memory cell), wherein the memory state the memory cell is residing in after the erasing may be called “erased state”. For example, erasing an n-type FET based memory cell may modify the state the memory cell is residing in from the LVT state to the HVT state, whereas erasing a p-type FET based memory cell may modify the state the memory cell is residing in from the HVT state to the LVT state.

Another example of a memory cell having at least two distinct states is a phase-change memory cell. The phase-change memory cell may include a phase change portion. The phase-change portion may be used to implement memory functions, e.g., in a memory cell. The phase-change portion may include a first phase state and a second phase state. For example, a phase-change memory cell may change from a first phase state to a second phase state or vice versa upon applying an electrical signal and may remain in the respective phase state for at least some time (referred to as retention time).

With reference to FIG. 1C, the memory structure 100 may be configured as a 1C1T (one capacitor, one transistor) memory cell. In this case the memory structure 100 may also be referred to as 1C1T ferroelectric capacitive memory (FCM) and/or as (e.g., non-volatile) FERAM. In this case, the first electrode 126 of the SPOC structure 120 may be configured to the first terminal 104 (as exemplarily shown in FIG. 1C) or to the second terminal 106. An access device, such as the field-effect transistor structure 110 (may also be referred to as access transistor), may allow to control an electrical behavior (e.g., a resistance R) of the channel region 112, thereby allowing to write the memory cell (by storing a charge in the capacitor of the SPOC structure 120) and/or read the memory cell (by detecting a voltage and/or current representing the charge stored in the capacitor of the SPOC structure 120). In this case, the second electrode 128 of the SPOC structure 120 may be connected to or may form a SPOC structure terminal 107.

According to various aspects, a memory device may include a memory cell and a controller (e.g., a memory controller) configured to operate (e.g., read and write) the memory cell. According to various aspects, a memory cell arrangement may include a memory cell and a controller (e.g., a memory controller) configured to operate (e.g., read and write) the memory cell. It is noted that some aspects are described herein with reference to a memory cell of a memory device and/or with reference to a memory cell of memory cell arrangement; it is understood that a memory device and/or a memory cell arrangement may include a plurality of such described memory cells according to various aspects that can be operated in the same way by the controller, e.g., at the same time or in a time sequence. A memory cell arrangement may further include respective sets of control lines and voltage supply levels configured to operate the one or more memory cells of the memory device and/or the memory cell arrangement.

It is noted that a memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well.

In general, a memory cell arrangement may include a plurality of (e.g., volatile or non-volatile) memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

The memory cell described herein (e.g., as part of a memory cell arrangement) may be used in connection with any type of suitable controller, e.g., a controller that may generate only two or only three different voltage levels for writing the memory cell (e.g., for writing one or more memory cells of a memory cell arrangement). However, in other aspects, more than four different voltage levels may be used for operating (e.g., for reading) the memory cell or for operating one or more memory cells of a memory cell arrangement.

According to various aspects, the memory cell described herein may be configured complementary metal oxide semiconductor (CMOS) compatible, e.g., including standard CMOS-materials only and may require no special integration considerations (e.g., no special thermal budget which may avoid diffusion and/or contamination during manufacturing). CMOS compatible spontaneously polarizable materials may be used to implement the one or more memory cell based on, for example, HfO₂ and/or ZrO₂. Doped HfO₂ (e.g., Si:HfO₂ or Al:HfO₂) or other suitable spontaneously-polarizable materials may allow for an integration of the spontaneously polarizable layer via known integration schemes.

According to various aspects, a controller may be configured to provide one or more sets of voltage levels to operate a memory cell arrangement (e.g., including a plurality of memory cells). According to various aspects, a writing operation may be provided based on only two voltage levels (e.g., a first supply voltage level VPP and a second supply voltage level VNN). In the case that the CMOS technology provides electrical access to the bulk, all bulks may be connected to VNN or a voltage significantly similar to VNN but such that no diode from bulk to any source/drain region is forward biased.

FIG. 1D schematically shows a memory cell arrangement 101A including two-terminal memory cells according to various aspects. Each two-terminal memory cell 102 may be configured as described with reference to FIG. 1A. The memory cell arrangement 101A may include an array of N times M memory cells. “N” may be any integer number equal to or greater than one. “M” may be any integer number equal to or greater than one.

The memory cell arrangement 101A may include a first set of control lines CL1(n=1 to N) and a second set of control lines CL2(m=1 to M) for individually addressing one or more of the memory cells.

The memory cell arrangement 101A may include a control circuit 103 (e.g., including a read-out circuit and/or a write circuit). The control circuit 103 may be configured to apply a first voltage at the first terminal 121 of a memory cell 102(m,n) via the corresponding control line CL1(n) of the first set of control lines and to apply a second voltage at the second terminal 123 of the memory cell 102(m,n) via the corresponding control line CL2(m) of the second set of control lines in order to address the memory cell 102(m,n).

FIG. 1E schematically shows a memory cell arrangement 101B including three-terminal memory cells according to various aspects. Each three-terminal memory cell 102 may be configured as described with reference to FIG. 1B.

The memory cell arrangement 101B may include a plurality, n, of first control lines, for example, a plurality of sourcelines SL(n). The memory cell arrangement 101B may include a plurality, n, of second control lines, for example, a plurality of drainlines DL(n). The memory cell arrangement 101B may include a plurality, m, of third control lines, for example, a plurality of wordlines WL(m). For each memory cell 102(m,n) of the plurality of memory cells, the first terminal 104 may be connected to a corresponding sourceline SL(n), the second terminal 106 may be connected to a corresponding drainline DL(n), and the third terminal 108 may be connected to a corresponding wordline WL(m).

The control circuit 103 may be configured to apply a first voltage, V_{S}, at the first terminal 104, a second voltage, VD, at the second terminal 106, and a third voltage, VG, at the third terminal 108 of a memory cell 102(m,n) in order to address the memory cell 102(m,n).

FIG. 1F schematically shows a memory cell arrangement 101C including three-terminal memory cells according to various aspects. Each three-terminal memory cell 102 may be configured as described with reference to FIG. 1C, wherein the SPOC structure 120 may be connected to the second terminal 106.

The memory cell arrangement 101C may include a plurality, n, of first control lines, CL1(n), for example a plurality of bitlines. The memory cell arrangement 101C may include a plurality, m, of second control lines CL2(n), for example a plurality of wordlines. The control circuit 103 may be configured to apply a first voltage at the first terminal 104 and a second voltage at the third (gate) terminal 108 in order to address the respective memory cell 102 (m, n). Here, the transistor may function as an access transistor for accessing the SPOC structure 120.

In some aspects, the SPOC structure terminal 107 may be at a base voltage (e.g., ground).

In other aspects, as exemplarily shown in the memory cell arrangement 101D in FIG. 1G, the memory cell arrangement 101D may include a plurality, n, of third control lines CL3(n), such as a plurality of platelines. The SPOC structure terminal 107 of a respective memory cell 102(m,n) may be connected to a corresponding one of the plurality of third control lines CL3(n). By this, writing of a respective memory cell may be improved.

It is understood that the memory cell arrangement 101A, the memory cell arrangement 101B, and the memory cell arrangement 101C serve as examples and that the memory cells 102 may be part of any suitable memory cell arrangement including corresponding control lines for addressing the memory cells 102. Further, it is understood that a memory cell arrangement may include further components such as one or more access devices for addressing the memory cells.

Herein, various exemplary configurations of the SPOC structure 120 are provided according to various aspects. For illustration, various of the configurations of the SPOC structure 120 are exemplarily shown for a planar configuration with planar layers. It is noted that other shapes may be suitable as well, such as curved shapes, angled shapes, coaxially aligned shapes, as examples. In this case, any layer described herein may have a non-planar (e.g., curved) structure. According to various aspects, the SPOC structure 120 may conformally cover a three-dimensional structure. Thus, the shape of the SPOC structure 120 may depend on (e.g., may substantially correspond to) the shape of this three-dimensional structure.

The phrase that “a layer conformally covers a structure” or that “a layer is disposed conformally over a structure” may be understood to mean that a thickness, which is measured normal (e.g., perpendicular) to a surface of the structure (e.g., the three-dimensional structure described herein), is substantially constant along the surface.

In various scenarios, it may be desired or even necessary to form one or more layers conformally over or on a three-dimensional structure, such as a trench. Here, ALD may be advantageous over other deposition methods (such as physical vapor deposition methods). In some cases, e.g., when a feature size (e.g., an aspect ratio) of the three-dimensional structure is equal to or greater than a threshold value (e.g., an aspect ratio equal to or greater than ten), ALD may even be required in order to form the one or more layers conformally over the three-dimensional structure (e.g., conformally within the trench).

According to various aspects, the three-dimensional structure may have a feature size (e.g., an aspect ratio) equal to or greater than six (e.g., equal to or greater than ten, e.g., equal to or greater than fifteen, e.g., equal to or greater than twenty, etc.)

In the exemplary case that the three-dimensional structure is a trench, the feature size may be given by the aspect ratio. The aspect ratio, may be defined by a ratio between the height, H, and the width, W (i.e., a=H/W). In the case of a curved trench, the width, W, may be measured at the surface of the substrate portion 202.

However, it is understood that the threshold value at which ALD may be required in order in order to form the one or more layers conformally over the three-dimensional structure may also depend on the width of the three-dimensional structure itself. For example, the width of the three-dimensional structure (e.g., as measured at the surface of the substrate portion 202 in the case of a trench) may be equal to or less than 200 nm, e.g., equal to or less than 100 nm, e.g., equal to or less than 50 nm (e.g., in combination with the aspect ratio described herein).

It is understood that atomic layer deposition (ALD) generally forms a layer conformally. Thus, in the case that herein a layer is formed over a structure using ALD, the layer is understood to be formed conformally over the structure. Hence, a layer formed over a structure using ALD conformally covers the structure.

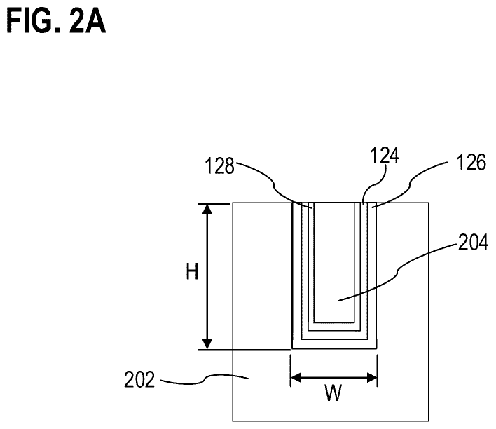

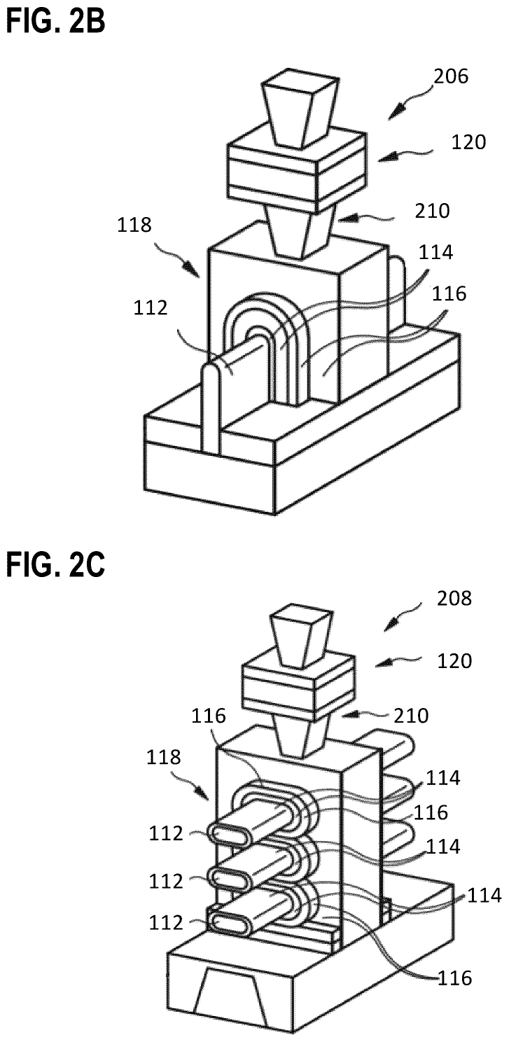

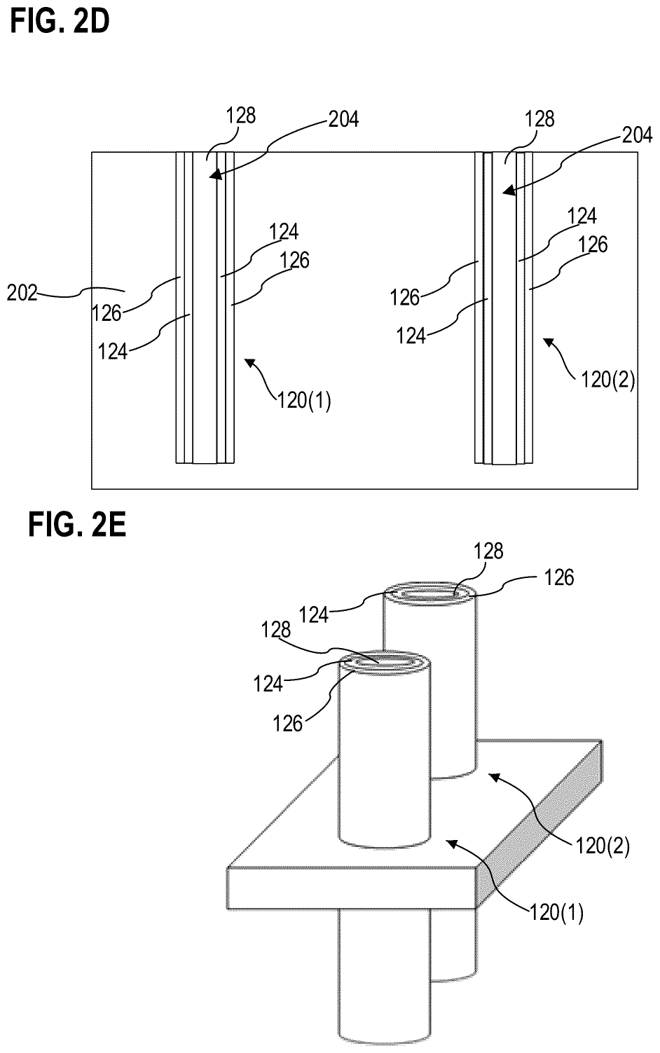

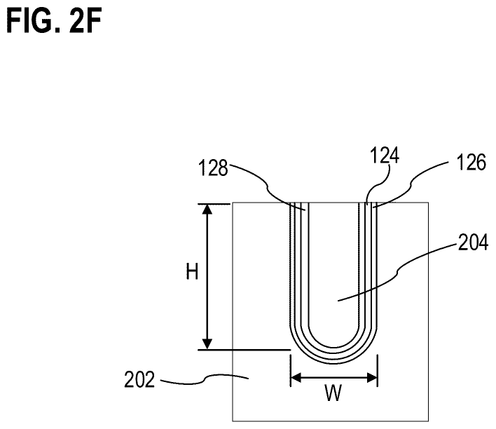

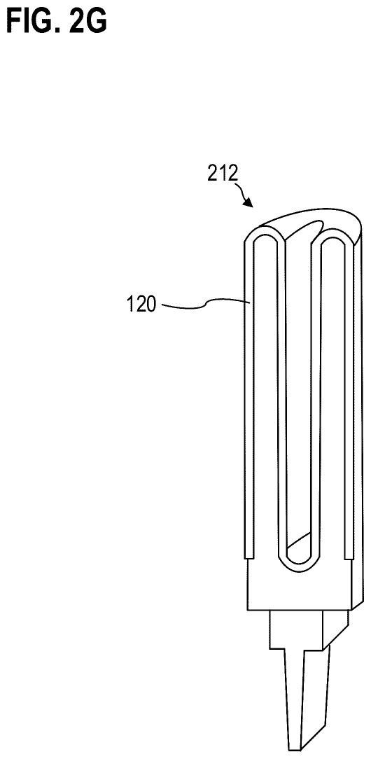

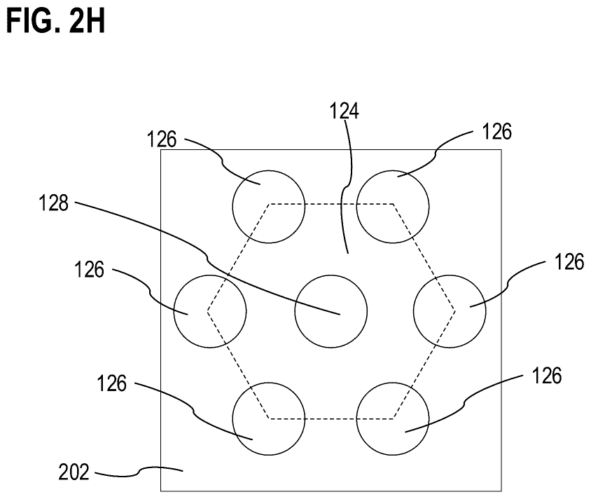

FIG. 2A shows, for illustration, a trench 204 as three-dimensional structure within a substrate portion 202. The SPOC structure 120 may be disposed within the trench 204. The layers of the SPOC structure 120 may be disposed conformally over the substrate portion 202 (i.e., may cover the substrate portion 202 conformally).

The trench 204 is shown in FIG. 2A as having a substantially rectangular shape. It is understood that this serves for illustration and that the trench 204 may have another shape. For example, at least a section of an inner wall of the trench 204 may be curved. As an example, a bottom portion of the trench 204 may be curved (see, for example, FIG. 2F). It is understood that the bottom surface and/or top surface of the trench 204 may have any suitable shape, such as one of the following: a circle, a square, a triangle, a parallelogram, a trapezoid, an ellipse, a polygon.

The trench 204 may have an aspect ratio equal to or greater than a threshold value (e.g., equal to or greater than six (e.g., equal to or greater than ten, e.g., equal to or greater than fifteen, etc.). As detailed herein, conformally forming the SPOC structure 120 within a trench 204 having an aspect ratio equal to or greater than the threshold value may require atomic layer deposition. As further detailed herein, it may not be possible to directly form a metal layer on an oxide layer (or at least not with satisfying and/or required electronic properties).

As described herein, the memory element 124 may substantially consists of an oxide material, such as one or more transition-metal-oxides (e.g., hafnium oxide, zirconium oxide, or HZO). Various aspects described herein allow to conformally form a metal electrode layer over the memory element 124 substantially consisting of the oxide material (e.g., using ALD).

According to various aspects, the substrate portion 202 may have an oxide layer at its interface to the SPOC structure 120. In some aspects, the substrate portion 202 may substantially consist of an oxide material. For example, the substrate portion 202 may substantially consist of a low-k material, such as silicon oxide (e.g., silicon dioxide). In other aspects, the oxide layer may be disposed (e.g., conformally) over the substrate portion 202 between the substrate portion 202 and the SPOC structure 120. For example, the oxide layer may be a natural or artificial oxide layer (e.g., a silicon oxide layer over the substrate portion 202 substantially consisting of silicon). Various aspects described herein allow to conformally form a metal electrode layer over the oxide layer (e.g., using ALD).

It is understood that the trench 204 serves as an example for illustration and that a “three-dimensional structure”, as described herein, may be any kind of three-dimensional structure such as a nanowire or nanoparticles on a surface of a substrate, or a surface of a porous substrate. A three-dimensional structure may be part of a ferroelectric tunnel junction and/or a selector element. It is understood that these three-dimensional structures are examples for illustration and that the SPOC structure 120 can be formed over other three-dimensional structures by employing the principles describes herein.

As an example, FIG. 2B shows an integration scheme of a memory cell 102 which may be configured as a fin field-effect transistor (FinFET). The substrate portion in which the channel region 112 is provided may have the shape of a vertical fin, wherein the gate isolation 114 and the gate electrode 116 may at least partially surround the fin.

In some aspects, the electrically conductive (e.g., ohmic) connection between the field-effect transistor structure 118 and the SPOC structure 120 may be provided by one or more metallization structures 210.

As a further example, FIG. 2C shows a memory cell 102 which may be configured as a nanosheet or nanowire field-effect transistor. The substrate portion(s), in which a respective channel region 112 is provided, may each have the shape of a nanosheet or nanowire. The gate isolation 114 and the gate electrode 116 may at least partially surround the respective nanosheets or nanowires.

Although the SPOC structure 120 of FIG. 2B and FIG. 2C is shown as being substantially planar, it is understood that the SPOC structure may also be non-planar (e.g., conformally disposed within or over the substrate portion 202.

As an even further example, FIG. 2D shows a cross-section of an exemplary arrangement of two SPOC structures 120(1), 120(2) within a cylindrical trench according to various aspects. FIG. 2E shows a perspective view thereof. As shown, in this scenario the SPOC structure 120 may have a cylindrical shape.

As another example, FIG. 2G shows a cross-section of an exemplary configuration in which the SPOC structure 120 is disposed on and/or within a cup 212. The cup 212 may be a (hollow) cylindrical structure similar to the ones of a (advanced) dynamic random access memory (DRAM).

As another example, FIG. 2H shows a top view on an exemplary SPOC structure 120 having a honeycomb-like structure (as indicated by the dashed hexagon). It is understood that the SPOC structure 120 may have a shape in accordance with any other polygon (e.g., having any other number of circular-shaped elements). Further, according to various aspects, the circular-shaped elements (e.g., of the honeycomb structure) may be connected to each other via one or more further structures. These further structure may, for example, serve as a support structure and/or as an electrically conductive connection.

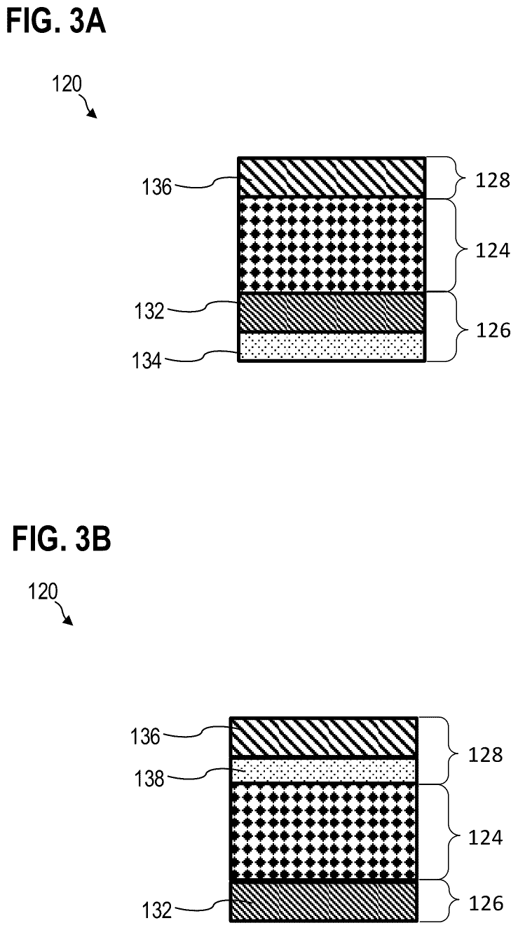

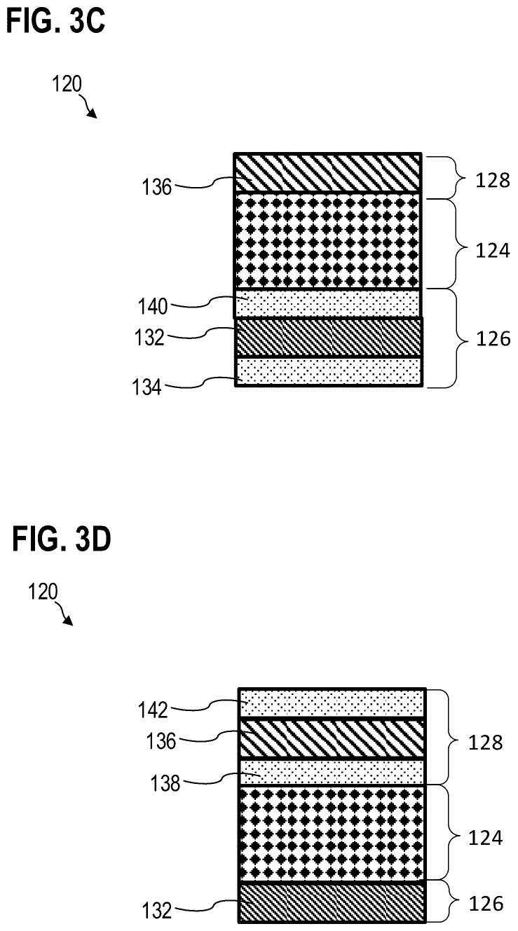

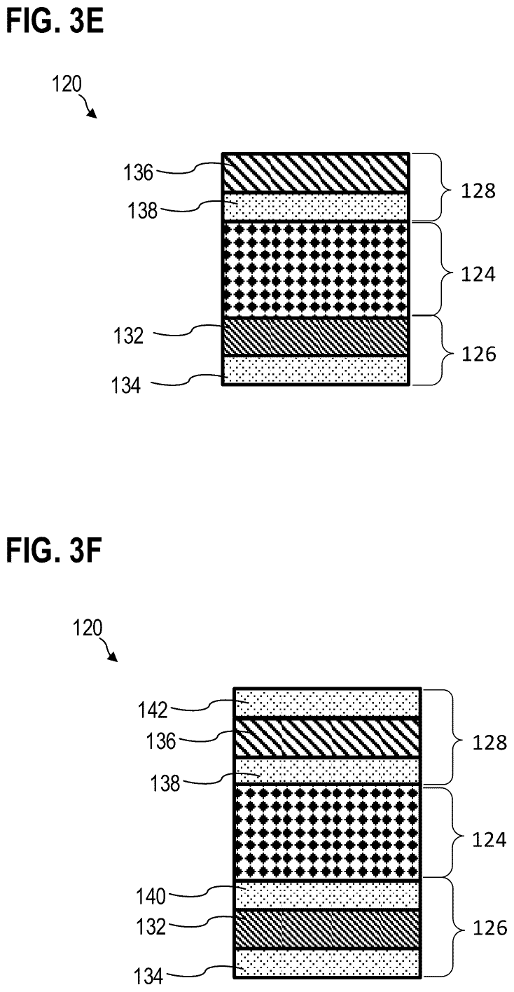

FIG. 3A to FIG. 3F, FIG. 5, and FIG. 7 each show an exemplary configuration of a SPOC structure 120 having a metal electrode layer over an oxide layer according to various aspects.

As described, the SPOC structure 120 may include the memory element 124 (e.g., substantially consisting of one or more transition-metal-oxides, the first electrode 126 (which may also be referred to as bottom electrode), and the second electrode 128 (which may also be referred to as top electrode).

With reference to FIG. 3A, FIG. 3C, FIG. 3E, and FIG. 3F, the first electrode 126 may include a first electrically conductive electrode layer 132 and a first functional layer 134. The first electrically conductive electrode layer 132 may be disposed between (and optionally in direct contact with) the first functional layer 134 and the memory element 124.

According to various aspects, the first electrically conductive electrode layer 132 may substantially consist of a first metal, such as Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc.

The first functional layer 134 may substantially consist of a first metal nitride or a first metal-oxynitride. The metal of the first metal nitride or the first metal-oxynitride may be Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc. In some aspects, the metal of the first metal nitride or the first metal-oxynitride may be the same metal as the first metal. In other aspects, the metal of the first metal nitride or the first metal-oxynitride may be a metal different from the first metal.

For example, in the case that the substrate portion 202 has the oxide layer at its interface (e.g., the substrate portion 202 substantially constating of a low-k material, such as silicon oxide), depositing a metal material (e.g., the first electrically conductive electrode layer 132) directly on the oxide layer using ALD may, for some metal materials, not be possible at all and may, for other metal materials, result in a damaged interface (due to an etching of a surface of the oxide layer), thereby significantly reducing the electronic properties of the memory cell. The use of the first functional layer 134 between the oxide layer and the first electrically conductive electrode layer avoids these problems.

The second electrode 128 may include a second electrically conductive electrode layer 136. As shown in FIG. 3A, FIG. 3C, FIG. 3E, and FIG. 3F, the second electrically conductive electrode layer 136 may be disposed directly on the memory element 124. This may be the case, when the second electrically conductive electrode layer 136 is not deposited using ALD and/or when the memory element 124 does not include (e.g., not substantially consist of) an oxide material and/or when the second electrically conductive electrode layer 136 does not substantially consist of a metal material. As an example, in this scenario, the second electrically conductive electrode layer 136 may include or may consist of a metal nitride. The metal nitride may be, for example, a titanium-based alloy (e.g., TiN, e.g., Ti—C—N, e.g., Ti—Al—N, e.g., TiN—TaN), a tantalum-based alloy (e.g., TaN, e.g., Ta—C—N, e.g., TaN—TiN), or a tungsten-based nitride (e.g., WN). As another example, in this scenario, the second electrically conductive electrode layer 136 may include or may consist of an oxidation resistant metal (e.g., a noble metal). The oxidation resistant metal may have an electronegativity greater than 1.85 on the Pauling scale. The oxidation resistant metal may have a melting temperature greater than 1450° C. This may reduce an oxidation of the interface of the second electrically conductive electrode layer 136. The oxidation resistant metal may include (e.g., consist of), for example, tungsten, platinum, iridium, ruthenium, palladium, osmium, rhodium, molybdenum, cobalt, rhenium, or nickel. According to various aspects, the second electrically conductive electrode layer 136 may have a work function of the oxidation resistant metal equal to or greater than 5 eV. According to various aspects, using oxidation resistant metal electrode(s) in combination with a spontaneously polarizable material which includes transition-metal-oxides (e.g., as a high-k capacitor dielectric) may suppress a charge injection due to the work function equal to or greater than 5 eV and a comparatively high band-offset. The band-offset may be a conduction band-offset for electrons (between Fermi-level of the electrode and the conduction band of the dielectric layers) or a valance band offset for holes (between Fermi-level of the electrode and the valence band of the dielectric layers).

With reference to FIG. 3B, FIG. 3D, FIG. 3E, and FIG. 3F, the second electrode 128 may include a second functional layer 138. The second functional layer 138 may be disposed between (and optionally in direct contact with) the memory element 124 and the second electrically conductive electrode layer 136.

According to various aspects, the second electrically conductive electrode layer 136 may substantially consist of a second metal, such as Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc. In some aspects, the first metal and the second metal may be a same metal material. In other aspects, the second metal may be a metal different from the first metal.

The second functional layer 138 may substantially consist of a second metal nitride or a second metal-oxynitride. The metal of the second metal nitride or the second metal-oxynitride may be Copper (Cu), Platinum (Pt), Iridium (Ir), Rhenium (Re), Rhodium (Rh), Palladium (Pd), Ruthenium (Ru), Titanium (Ti), Osmium (Os), Molybdenum (Mo), Chromium (Cr), Tungsten (W), Silver (Ag), Aluminum (Al), Gold (Au), Cobalt (Co), etc. In some aspects, the metal of the second metal nitride or the second metal-oxynitride may be the same metal as the second metal. In other aspects, the metal of the second metal nitride or the second metal-oxynitride may be a metal different from the second metal.

For example, in the case that the memory element 124 includes an oxide material (e.g., in the case that the memory element 124 substantially consists of one or more transition-metal-oxides, such as HZO), depositing a metal material (e.g., the second electrically conductive electrode layer 136) directly on the memory element 124 using ALD may, for some metal materials, not be possible at all and may, for other metal materials, result in a damaged interface (due to an etching of a surface of the memory element 124), thereby significantly reducing the electronic properties of the memory cell. The use of the second functional layer 138 between the memory element 124 and the second electrically conductive electrode layer 136 avoids these problems.

As shown in FIG. 3B and FIG. 3D, the SPOC structure 120 may, in some aspects, include the second functional layer 138 but not the first functional layer 134. This may be the case, when the first electrically conductive electrode layer 132 is not deposited using ALD and/or when the substrate portion 202 does not have the oxide layer at its interface to the SPOC structure 120 and/or when the first electrically conductive electrode layer 132 does not substantially consist of a metal material. As an example, in this scenario, the first electrically conductive electrode layer 132 may include or may consist of a metal nitride. The metal nitride may be, for example, a titanium-based alloy (e.g., TiN, e.g., Ti—C—N, e.g., Ti—Al—N, e.g., TiN—TaN), a tantalum-based alloy (e.g., TaN, e.g., Ta—C—N, e.g., TaN—TiN), or a tungsten-based nitride (e.g., WN). As another example, in this scenario, the first electrically conductive electrode layer 132 may include or may consist of an oxidation resistant metal (e.g., a noble metal). The oxidation resistant metal may have an electronegativity greater than 1.85 on the Pauling scale. The oxidation resistant metal may have a melting temperature greater than 1450° C. This may reduce an oxidation of the interface of the first electrically conductive electrode layer 132. The oxidation resistant metal may include (e.g., consist of), for example, tungsten, platinum, iridium, ruthenium, palladium, osmium, rhodium, molybdenum, cobalt, rhenium, or nickel. According to various aspects, the first electrically conductive electrode layer 132 may have a work function of the oxidation resistant metal equal to or greater than 5 eV. According to various aspects, using oxidation resistant metal electrode(s) in combination with a spontaneously polarizable material which includes transition-metal-oxides (e.g., as a high-k capacitor dielectric) may suppress a charge injection due to the work function equal to or greater than 5 eV and a comparatively high band-offset. The band-offset may be a conduction band-offset for electrons (between Fermi-level of the electrode and the conduction band of the dielectric layers) or a valance band offset for holes (between Fermi-level of the electrode and the valence band of the dielectric layers).

Thus, according to various aspects, the first electrically conductive electrode layer 132 may be deposited on the first functional layer 134 using ALD and/or the second electrically conductive electrode layer 136 may be deposited on the second functional layer 138 using ALD. Illustratively, the first functional layer 134 and the second functional layer 138 can be or serve as a nucleation layer for the respective electrode layer.

Experimental investigations revealed that, in the case that the first metal and/or the second metal is tungsten, it is not possible to deposit tungsten directly on an oxide material (e.g., silicon oxide of the substrate portion 202 and/or one or more transition-metal-oxides of the memory element) using ALD. But carrying out an ALD of tungsten results in an etching of the oxide material. Further, it has been found that the functional layer (e.g., the first functional layer 134 and/or the second functional layer 138) may, depending on the material of the metal nitride or metal-oxynitride and/or the metal material of the respective electrically conductive electrode layer, require a minimum thickness in order to allow a deposition of the metal material. For example, investigations revealed that depositing tungsten using ALD over an oxide layer may, in the case that the functional layer substantially consists of titanium nitride, require a thickness of the functional layer greater than 1 nm. It has been found that in the case of a titanium nitride layer having a thickness of about 1 nm an ALD of tungsten also results in a (at least local) etching of the oxide layer below. Therefore, according to various aspects, the first functional layer 134 and/or the second functional layer 138 may have a thickness greater than 1 nm, optionally in a range from about 1.1 nm to about 5 nm.

According to various aspects, the first electrode 126 and/or the second electrode 128 may be symmetric. Thus, the first electrode 126 may, in addition to the first functional layer 134, further include a further first functional layer 140 over (e.g., directly on) the first electrically conductive electrode layer 132 (see, for example, FIG. 3C and FIG. 3F). Accordingly, the second electrode 128 may, in addition to the second functional layer 138, further include a further second functional layer 142 over (e.g., directly on) the second electrically conductive electrode layer 136 (see, for example, FIG. 3D and FIG. 3F). Having such a symmetric electrode may improve the electronic properties of the memory cell. Illustratively, the respective electrically conductive electrode layer may be sandwiched between two functional layers.

According to various aspects, the memory element 124 may substantially consist of one or more transition-metal-oxides and the metal of the metal nitride or metal-oxynitride of the first functional layer 134 and/or the second functional layer 138 may be a transition metal of the one or more transition-metal-oxides. Hence, the metal nitride may, for example, be hafnium nitride or zirconium nitride in the case that the memory element 124 substantially consists of hafnium oxide, zirconium oxide, or hafnium zirconium oxide.

According to various aspects, a memory cell arrangement (e.g., a dynamic random access memory, DRAM) may include a plurality of memory cells each including the SPOC structure 120 described herein. The memory cell arrangement may include a substrate providing the substrate portions (202) of the plurality of memory cells. For example, the substrate may be a silicon substrate (e.g., including one or more electronic devices) having an oxide layer substantially consisting of a low-k material, such as silicon oxide, disposed thereon. The memory cell arrangement may include a plurality of sets of control lines for selectively addressing one or more memory cells of the plurality of memory cells.

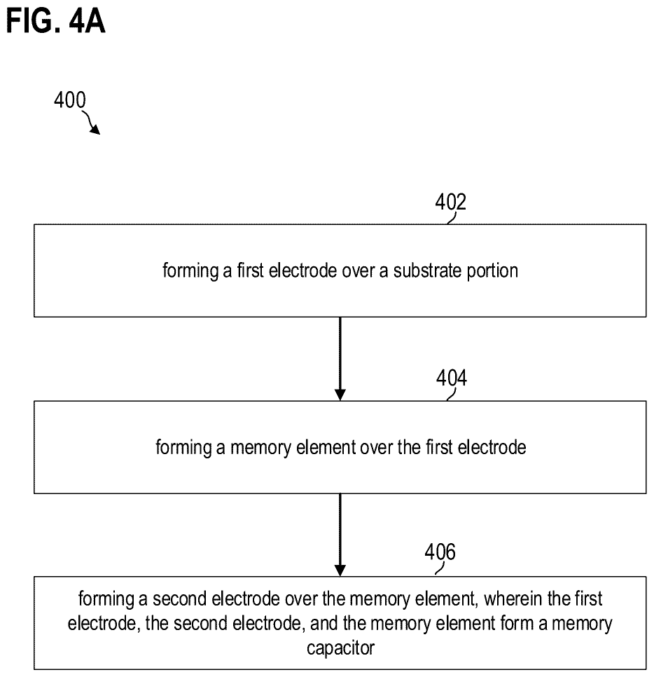

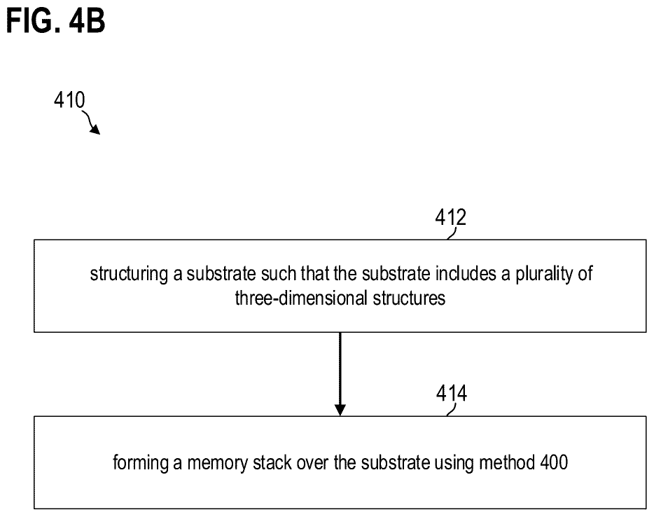

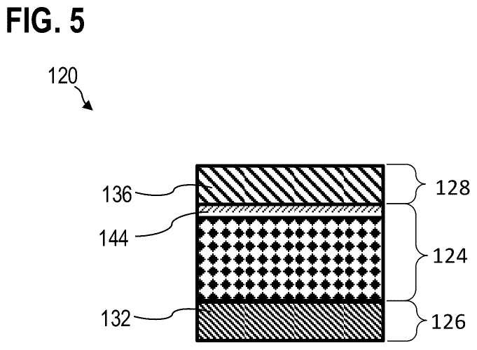

FIG. 4A shows a flow diagram of a method 400 of manufacturing a memory cell according to various aspects. The memory cell may include the SPOC structure 120 described herein.

The method 400 may include forming a first electrode (e.g., the first electrode 126) over a substrate portion (e.g., the substrate portion 202) (in 402). As detailed herein, the first electrode 126 may include the first functional layer 134 and the first electrically conductive electrode layer 132. Accordingly, forming the first electrode may include forming a first functional layer (e.g., the first functional layer 134) substantially consisting of a first metal nitride or a first metal-oxynitride using atomic layer deposition and forming a first electrically conductive electrode layer (e.g., the first electrically conductive electrode layer 132) substantially consisting of a first metal directly on the first functional layer using atomic layer deposition.

As detailed herein, the first electrode 126 may include the further first functional layer 140. Accordingly, forming the first electrode may include forming a further first functional layer (e.g., the further first functional layer 140) substantially consisting of the first metal nitride or the first metal-oxynitride directly on the first electrically conductive electrode layer (prior to forming memory element).

The method 400 may include forming a memory element (e.g., the memory element 124) over the first electrode (in 404).

The method 400 may include forming a second electrode (e.g., the second electrode 128) over the memory element (in 406). The first electrode, the memory element, and the second electrode may form a memory capacitor (e.g., the SPOC structure 120). As detailed herein, the second electrode 128 may include the second functional layer 138 and the second electrically conductive electrode layer 136. Accordingly, forming the second electrode may include forming a second functional layer (e.g., the second functional layer 138) substantially consisting of a second metal nitride or a second metal-oxynitride directly on the memory element using atomic layer deposition and forming a second electrically conductive electrode layer (e.g., the second electrically conductive electrode layer 136) substantially consisting of a second metal directly on the second functional layer using atomic layer deposition.

As detailed herein, the second electrode 128 may include the further second functional layer 142. Accordingly, forming the second electrode may include forming a further second functional layer (e.g., the further second functional layer 142) substantially consisting of the second metal nitride or the second metal-oxynitride directly on the second electrically conductive electrode layer (prior to forming memory element).

According to various aspects, at least one electrode layer disposed over an oxide layer may be formed using atomic layer deposition (ALD). In some aspects, at least one other layer may be formed using a vapor deposition different from ALD (e.g., a physical vapor deposition (PVD), such as sputtering, or chemical vapor deposition (CDV) different from ALD).

In general, an atomic layer deposition (ALD) of a layer may include various cycles and/or sub-cycles. Each cycle may include one or more precursor pulses and a respective purging after each precursor pulse of the one or more precursor pulses. A precursor pulse may be associated with injecting a gas which includes a respective material of one or more materials to be deposited into a processing chamber in which the memory capacitor is (or is to be) processed. A precursor pulse may be associated with a pulse time defining a time for which the gas is injected into the processing chamber. Each pulse, described herein, may also be associated with a respective process temperature representing a temperature of the substrate and/or the already formed part of the memory capacitor. After each precursor pulse of the one or more precursor pulses, a respective purging may be carried out. Hence, for example, a purging may be carried out between a precursor pulse and a consecutive pulse of an oxidizer (in the case of depositing an oxide layer), or vice versa. A purging may include a purging of remaining gas associated with the respective pulse (e.g., precursor pulse or oxidizer pulse). The purging of the remaining gas may include a purging with another gas, such as nitrogen (N₂). Alternatively, such as in the case of spatial ALD, gas barriers (e.g., a N₂ barrier) may be used instead of purging. Thus, it is understood that between two consecutive pulses described herein (e.g., between a precursor pulse and an oxidizer pulse, or vice versa), a purging may be carried out and/or the substrate may be moved through a gas barrier (e.g., into another chamber).

An atomic layer of a metal layer may be formed by a precursor pulse associated with the metal. According to various aspects, the first electrically conductive electrode layer and/or the second electrically conductive electrode layer may be formed by atomic layer deposition using a metal-organic precursor or a halide precursor. As an example, the first metal and/or the second metal may be tungsten. In this case, the halide precursor may be tungsten fluoride (WF₆). The halide precursor may be used in combination with one or more reducing agents. A reducing agent may be, for example, silane (SiH₄), disilane (Si₂H₆), or diborane (B₂H₆). The deposition may be carried out at a temperature in a range from about 150° C. to about 350° C.

According to various aspects, forming the first functional layer substantially consisting of the first metal nitride may include forming the first functional layer by atomic layer deposition using a halide precursor in combination with a nitridation agent or using a metal-organic precursor containing nitrogen in combination with a reducing agent. Accordingly, forming the second functional layer substantially consisting of the second metal nitride may include forming the second functional layer by atomic layer deposition using a metal-organic precursor or a halide precursor.

As a first example, the first metal nitride or the second metal nitride may be titanium nitride. Titanium nitride may be deposited by ALD using TiCl₄ as halide precursor in combination with NH₃ as nitridation agent. This ALD process may be carried out at a temperature of about 430° C. According to some aspects, an additional reducing agent, such as Zn gas, H2, and/or Trimethylaluminum (TMA) may be used (e.g., which allows to decrease the reaction temperature). Alternatively, titanium nitride may be deposited by ALD using a nitrogen containing metalorganic precursor in combination with a reducing agent, such as Ti(NMe₂)₄ [(CH₃)₂N]₄Ti (TDMAT) as metalorganic precursor in combination with H₂ as reducing agent. This ALD process may be carried out at a temperature of about 200° C.

As a second example, the first metal nitride or the second metal nitride may be tungsten nitride. Tungsten nitride may be, in general, deposited by ALD using tungsten fluoride as described above and a subsequent nitridation with ammonia. However, as detailed herein, tungsten fluoride may at least partially etch a surface of the oxide layer and/or the tungsten layer may not even grow on the oxide. Therefore, according to various aspects, tungsten nitride may be deposited by ALD using a metalorganic precursor, such as W(NMe₂)₂ (NCMe₃)₂ (e.g., at a temperature of about 400° C.) or (^{t}BuN)₂ (Me₂N)₂W (e.g., at a temperature in a range from about 250° C. to about 350° C.), in combination a reducing agent, such as ammonia (NH₃). Alternatively, tungsten nitride may be deposited by plasma-enhanced ALD (PE-ALD) using tris(3-hexyne) W(CO) as a metalorganic precursor in an NH₃ plasma.

Various aspects refer to a precursor pulse of a transition metal. The precursor pulse of the transition metal may include injecting a precursor gas which includes the transition metal into the processing chamber. It is understood that the precursor gas may include other components as well; however, the precursor gas may be configured such that, at least after a purging, substantially only atoms of the transition metal are deposited at a surface of the processed memory capacitor. For example, the transition metal may be hafnium and the precursor gas may include hafnium, such as Tetrakis-(ethylmethylamido)-hafnium (TEMA-Hf) or Tetrakis-(dimethylamido)-hafnium (TDMA-Hf). For example, the transition metal may be zirconium and the precursor gas may include zirconium, such as Tetrakis-(ethylmethylamido)-zirconium (TEMA-Zr) or Tetrakis-(dimethylamido)-zirconium (TDMA-Zr). Any chemistry associated with the atomic layer deposition capable to remove ligands of the respective precursor may be used.

An atomic layer of a layer, which includes an oxide, may be formed by a respective precursor pulse of one or more materials and a pulse of an oxidizer (in some aspects referred to as oxidizer pulse) to oxidize the one or more materials. In some aspects, the pulse of an oxidizer may be referred to as precursor pulse of the oxidizer. A pulse of an oxidizer may include injecting a predefined concentration of the oxidizer (e.g. >200 g/m³) into the processing chamber. The oxidizer (in some aspects referred to as oxidizing agent) may include or may be O₃, H₂O, and/or O₂. For example, a respective pulse time of each pulse of an oxidizer may be in the range from about 1 second to about 30 seconds.

Various aspects refer to a pulse of an oxidizer. It is understood that a gas associated with the oxidizer may consist of oxygen atoms, such as O₂, or O₃, or may include other components as well, such as H₂O or H₂O₂.

According to various aspects, forming a layer (e.g., the first functional layer 134 and/or the second functional layer 138) substantially consisting of a metal-oxynitride (e.g., the first metal-oxynitride and/or the second metal-oxynitride, respectively) may include forming a layer substantially consisting of a metal nitride using atomic layer deposition (with the metal of the metal nitride being the metal of the metal-oxynitride) and oxidizing the metal nitride of the layer to thereby form the (e.g., highly oxidized) metal-oxynitride.

Optionally, the method 400 may include forming the three-dimensional structure prior to forming (in 402) the first electrode. For example, the three-dimensional structure may be a trench (such as trench 204) and forming the three-dimensional structure may include etching the substrate portion to form the trench. In some aspects, the substrate portion may substantially consist of the oxide material. In other aspects, the method 400 may further include forming (e.g., depositing) an oxide layer directly on the three-dimensional structure (e.g., conformally (at least) within the trench).

According to various aspects, the first functional layer 134 and/or the second functional layer 138 may be a functional layer stack.

The functional layer stack may include a (first) functional layer substantially consisting of a metal nitride or a metal-oxynitride and/or a (second) functional layer substantially consisting of a metal and/or a (third) functional layer substantially consisting of a metal oxide in any arbitrary order. In the case that the (third) functional layer substantially consisting of the metal oxide may be the topmost layer, the layer may be a sacrificial layer at least partially etched during ALD of the first electrically conductive electrode layer 132 and/or the second electrically conductive electrode layer 136.

The functional layer stack may include a (first) functional layer substantially consisting of a metal-oxynitride and a (second) functional layer substantially consisting of a metal nitride (e.g., directly on the first functional layer). In this case, the method 400 may include forming (e.g., by ALD) a metal nitride functional layer (substantially consisting of a metal nitride) over (e.g., directly on) the memory element 124, oxidizing the metal nitride of the metal nitride functional layer to thereby form the metal-oxynitride functional layer, and then forming (e.g., by ALD) another metal nitride functional layer (substantially consisting of a (e.g., the) metal nitride) over (e.g., directly on) the metal-oxynitride functional layer.

A material of the first electrically conductive electrode layer 132 and/or of the second electrically conductive electrode layer 136 may have an electrical conductivity greater than 106 S/m at a temperature of 20° C. The first electrically conductive electrode layer 132 and/or the second electrically conductive electrode layer 136 may have a thickness less than 10 nm, for example less than 5 nm, for example less than 2 nm. The coefficient of thermal expansion of the first electrically conductive electrode layer 132 and/or the second electrically conductive electrode layer 136 may be below 7 ppm.

A spontaneously polarizable material (e.g., HZO) of the memory element 124 may exhibit the spontaneously polarizable properties only in the crystalline phase. According to some aspects, the spontaneously polarizable material may be deposited already in the crystallized state. According to other aspects, the spontaneously polarizable material may be deposited substantially amorphous and crystallized afterwards. Hence, herein the material of the memory element 124 may be referred to as spontaneously polarizable material even in the amorphous state prior to exhibiting the spontaneously polarizable properties responsive to crystallization.

The spontaneously polarizable material (e.g., HZO) of the memory element 124 may be crystallized by annealing (e.g., thermally annealing). The annealing may include a furnace annealing, a flash-lamp annealing, and/or a laser annealing. The annealing may be carried out in an inert gas atmosphere (e.g., nitrogen, e.g., argon) at any suitable pressure, e.g., at atmospheric pressure, at a pressure below atmospheric pressure, or at a pressure above atmospheric pressure. In some aspects, the annealing may be carried out in a vacuum. A vacuum in a processing chamber (e.g., for depositing a material and/or for annealing a material) may be provided in a pressure range below 50 mbar. According to various aspects, the memory element 124 may be annealed using a laser annealing and/or a flash-lamp annealing with local temperatures in the range from about 1500° C. to about 1850° C. The local temperatures in the range from about 1500° C. to about 1850° C. may result in homologous temperature, T_{H}, of the capacitive memory structure given by a temperature, T, over a melting temperature of the one or more transition-metal-oxides, Tₘₑₗₜ, in the range from about 0.6 to about 0.7 or greater than 0.7. For example, it may be possible to crystallize the HZO into the ferroelectric phase by annealing at temperatures in a range from about 300° C. to about 400° C. The crystallized spontaneously polarizable material may be polycrystalline including a plurality of crystallites and the crystallites may have the predefined crystallographic texture, as achieved by means of the amorphous functional layer(s). As an example, a majority of the crystallites (e.g., at least 50%, e.g., at least 75%, e.g., at least 90% of the crystallites) may be oriented along the same direction and therefore define a crystallographic texture. The term “texture”, as used herein, may describe a crystallographic texture as a property of a material or of a layer including a material. The crystallographic texture may be related to a distribution of crystallographic orientations of crystallites of a polycrystalline material. The crystallographic texture may be described by an orientation distribution function (ODF). A crystallographic texture of a layer, as referred to herein, may describe a preferred orientation of the crystallites of a polycrystalline material with reference to a surface of the layer. A crystallographic texture of a layer, as referred to herein, may describe a preferred orientation of the crystallites of a polycrystalline material with reference a direction of an external electric field caused by a voltage applied to electrodes contacting the layer. In other words, a material or layer consisting of crystallites may have no texture in the case that the orientations of the crystallites are randomly distributed. The material or layer may be regarded as a textured material or layer in the case that the orientations of the crystallites show one or more preferred directions. For example, a (001)-texture of the spontaneously polarizable memory layer may describe that most of the crystallites of the polycrystalline material that forms at least part of the spontaneously polarizable memory layer are oriented with their (001)-lattice planes along a direction perpendicular to the (e.g., upper) surface of the spontaneously polarizable memory layer. For example, a (001)-texture of the spontaneously polarizable material of the memory element 124 may describe that most of the crystallites of the polycrystalline material that forms at least part of the spontaneously polarizable material are oriented with their (001)-lattice planes along a direction perpendicular to a growth direction associated with the spontaneously polarizable material. As another example, a (111)-texture of the spontaneously polarizable material of the memory element 124 may describe that most of the crystallites of the polycrystalline material that forms at least part of the spontaneously polarizable material are oriented with their (111)-lattice planes along a direction perpendicular to the (e.g., upper) surface of the spontaneously polarizable material. For example, a (111)-texture of the spontaneously polarizable material may describe that most of the crystallites of the polycrystalline material that forms at least part of the spontaneously polarizable memory layer are oriented with their (111)-lattice planes along a direction perpendicular to a growth direction associated with the spontaneously polarizable memory layer. The (001)-texture may be a (001)-fiber-texture or a (001)-biaxial-texture. The (111)-texture may be a (111)-fiber-texture or a (111)-biaxial-texture. In general, the crystallographic texture may be described by the orientation distribution function (ODF), wherein x-ray diffraction patterns (e.g., pole-figure measurements, e.g., theta-2theta x-ray diffraction measurements with a scattering vector in plane-normal direction, such as perpendicular to a surface of electrodes of a planar capacitive memory structure) or other suitable measurements, e.g., based on transmission electron microscopy, electron backscatter diffraction (EBSD), or transmission Kikuchi diffraction (TKD), may be used to determine the orientation of the crystalline grains of the material.

In some aspects, the substrate may include or may be a silicon substrate e.g., with or without a (e.g., native) SiO₂ surface layer, or any other suitable semiconductor substrate. In other aspects, the substrate may include or may be an electrically non-conductive substrate, e.g., a glass substrate. In still other aspects, the substrate may include or may be an electrically conductive substrate, e.g., a metal substrate.

FIG. 4B shows a flow diagram of a method 410 of manufacturing a memory cell arrangement according to various aspects. The method 410 may include structuring a substrate such that the substrate includes a plurality of three-dimensional structures (in 412). The method 410 may include forming a memory layer stack over the substrate using method 400. The method 410 may include structuring the memory layer stack to form a plurality of memory cells. According to various aspects, the plurality of memory cells may be formed simultaneously. The method 410 may include (at least partially after and/or at least partially prior to forming the memory cells) forming a plurality of sets of control lines for selectively addressing one or more memory cells of the plurality of memory cells.

With reference to FIG. 5, the SPOC structure 120 may include a third functional layer 144. The third functional layer 144 may be disposed between and in direct contact with the memory element 124 and the second electrode 128. In this example, the memory element 124 may substantially consist of the one or more transition-metal-oxides (e.g., HZO).

Optionally, the SPOC structure 120 may be further configured in accordance with the SPOC structure 120 described with reference to any of FIG. 3A to FIG. 3F (e.g., including the first functional layer 134 and/or the second functional layer 138).

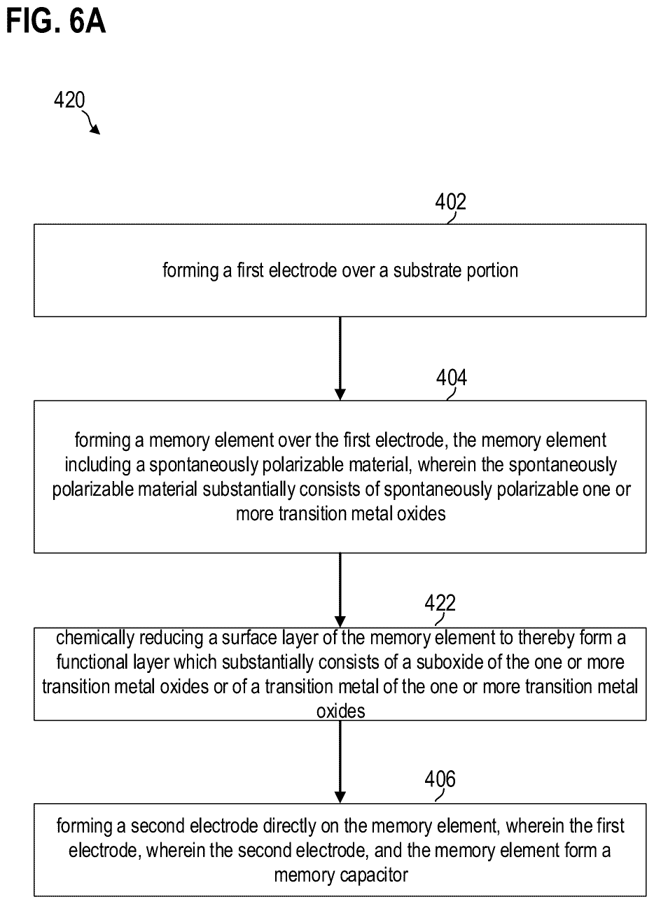

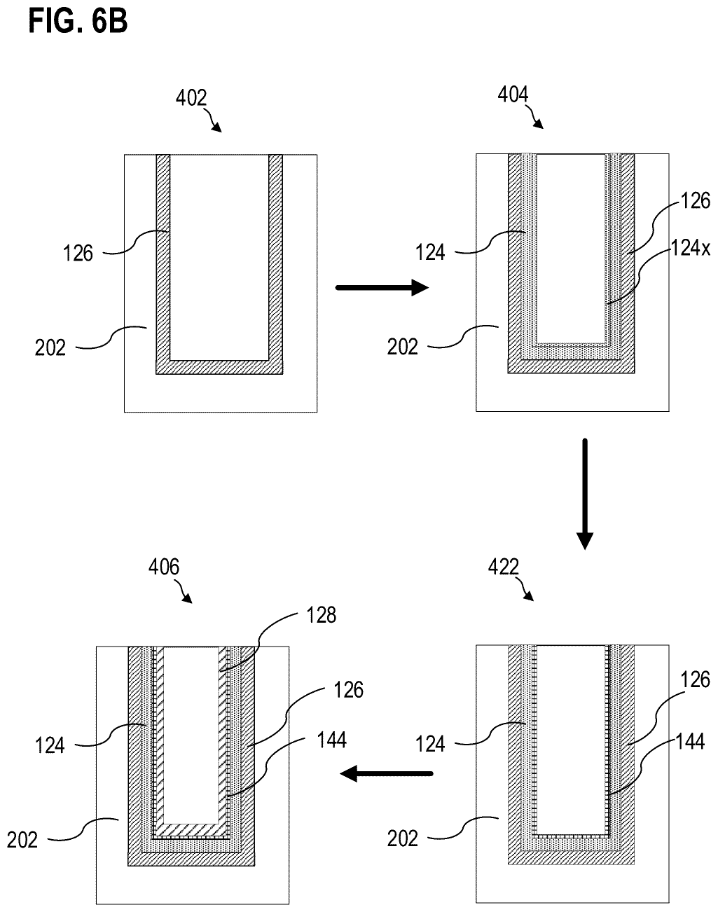

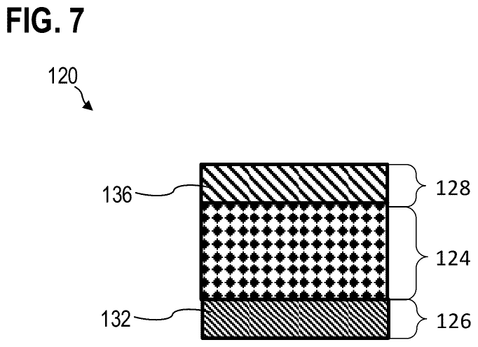

The method 400 may include forming the third functional layer 144 prior to forming the second electrode 128. A flow diagram of an exemplary method 420 is shown in FIG. 6A. Here, the method 420 may include (in 422) reducing a surface layer of the memory element 124 to thereby form the third functional layer (which substantially consists of a suboxide of the one or more transition-metal-oxides or of a transition metal of the one or more transition-metal-oxides).

The term “reducing” with respect to a layer may be understood to mean a chemical reduction, e.g., a redox-reaction.

According to some aspects, the third functional layer 144 may substantially consist of a suboxide of the one or more transition-metal-oxides. In this case, method 400 may include forming the third functional layer 144 by reducing the surface layer of the memory element 124 to a suboxide of the one or more transition-metal-oxides. The term “suboxide”, as used herein, may indicate that the layer includes the same one or more transition-metal-oxides but has a lower oxygen content. For example, in the case that the one or more transition-metal-oxides are HZO (Hf₁₋ₓZrₓO₂), the suboxide may be hafnium zirconium oxide given by Hf₁₋ₓZrₓO_{2-y} (with y being greater than zero).

According to other aspects, the third functional layer 144 may substantially consist of a transition-metal of the one or more transition-metal-oxides. In this case, method 400 may include forming the third functional layer 144 by reducing the surface layer of the memory element 124 to a transition-metal of the one or more transition-metal-oxides. For example, the one or more transition-metal-oxides may be HZO (hafnium zirconium oxide) and the third functional layer 144 may be formed by reducing the HZO to hafnium or to zirconium or to a hafnium-zirconium-alloy.

Illustratively, the method 400, 420 may include a surface treatment (e.g., using a reducing agent) to create a surface layer of suboxide or metal (as a third functional layer). This surface layer may then act as a nucleation layer (may also be referred to as adhesion layer) for depositing the second functional layer 138 by ALD using a metal precursor (e.g., WF₆). In some aspects, the suboxide may be more resistant to the etching due to the metal precursor (e.g., WF₆) as compared to the initial layer.

FIG. 6B shows exemplary configurations of this structure during the manufacturing the SPOC structure 120 conformally over the substrate portion 202 within the trench 204. In 402, the first electrode may be formed over the substrate portion 202 using ALD. It is understood that forming a layer may include forming a first layer over a whole surface of the substrate and subsequently etching part of the formed first layer to form the layer. As described herein, the forming the first electrode 126 may include forming the first electrically conductive electrode layer 132 and optionally forming the first functional layer 134 prior to forming the first electrically conductive electrode layer 132. In 404, the memory element memory element 124 may be formed over the first electrode 126. The memory element 124 may have a surface layer 124x. In 422, this surface layer 124x may be reduced to a reduced surface layer, thereby forming the third functional layer 144. In 406, the second electrode 128 may be formed over (e.g., directly on) the third functional layer 144. As described herein, the forming the second electrode 128 may include forming the second electrically conductive electrode layer 136 and optionally forming the second functional layer 138 prior to forming the second electrically conductive electrode layer 136. Although the second electrode 128 is shown as a conformal layer, in some aspects, the second electrode 128 may fill the trench 204 completely.

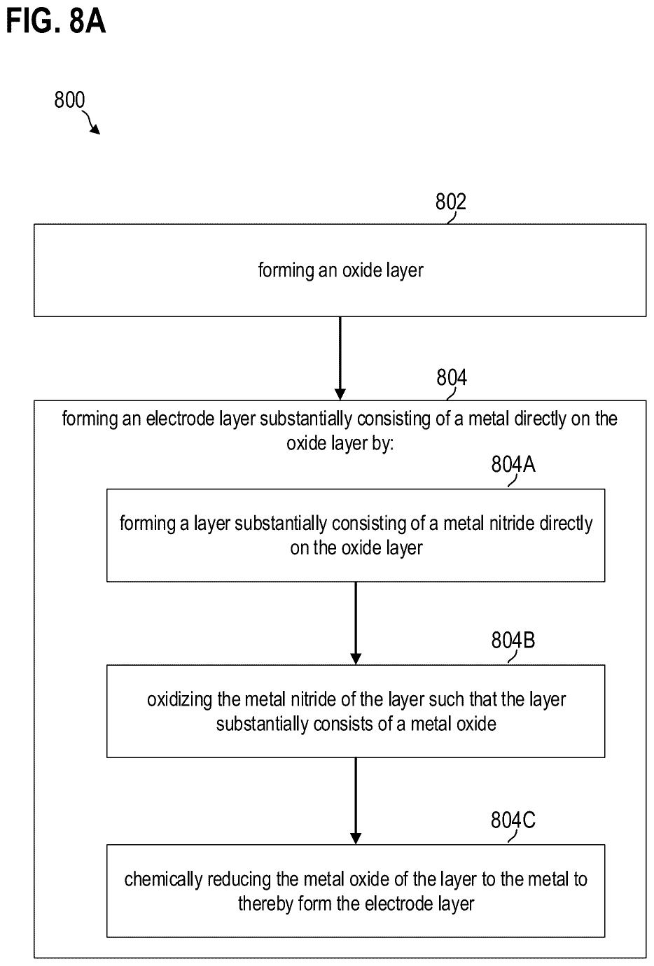

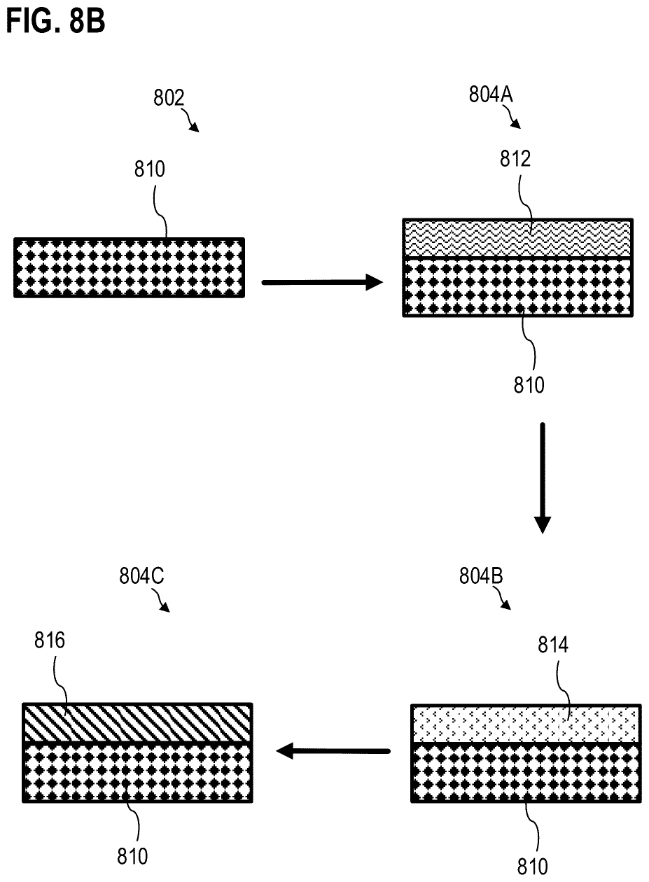

FIG. 7 shows an exemplary configuration of the SPOC structure 120 in which the second electrically conductive electrode layer 136 is directly disposed over the memory element 124 and may still substantially consist of the first metal. FIG. 8A shows a flow diagram of a method 800 which allows to generate a metal electrode layer directly on an oxide layer according to various aspects (such as the second electrically conductive electrode layer 136 directly on the memory element 124).

The method 800 may include forming an oxide layer (in 802). In the case of the SPOC structure 120, the oxide layer may be the oxide or oxide layer of the substrate portion 202 or may be the one or more transition-metal-oxides of the memory element 124. However, it is understood that the SPOC structure 120 is only an example and that the method 800 may be employed for any other kind of oxide layer, such as an oxide layer of a battery structure.

The method 800 may include forming an electrode layer substantially consisting of a metal directly on the oxide layer (in 804).

Forming the electrode layer (in 804) may include forming a layer substantially consisting of a metal nitride directly on the oxide layer (in 804A). The metal of the metal nitride may correspond to the metal of the electrode layer to be formed. The metal nitride may be one of: titanium nitride (TiN), tungsten nitride (WN), molybdenum nitride (MoN), tantalum nitride (TaN), niobium nitride (NbN), hafnium nitride (HfN), or zirconium nitride (ZrN).

Forming the electrode layer (in 804) may further include oxidizing the metal nitride of the layer such that the layer substantially consists of a metal oxide (hence, the metal of the metal oxide corresponds to the metal of the metal nitride) (in 804B).

Forming the electrode layer (in 804) may further include reducing the metal oxide of the layer to the metal to thereby form the electrode layer (in 804C).

Illustratively, a metal layer may be formed by depositing a metal nitride, oxidizing the metal nitride to a metal oxide, and then reducing the metal oxide to the metal.

In some aspects, the metal (material) described above may be a metalloid. Thus, also a metal nitride may be a metalloid nitride, a metal oxide may be a metalloid oxide, etc.

FIG. 8B shows exemplary configurations of the memory cell during the generation of the metal layer. In 802, an oxide layer can be formed. In some aspects, the oxide layer 810 may be part of the substrate such that the method 800 may start with 804, i.e., forming the electrode layer substantially consisting of the metal directly on the oxide layer. In 804A, a metal nitride layer 812 may be formed directly on the oxide layer 810. The metal nitride layer 812 may substantially consist of a metal nitride. In 804B, the metal nitride layer 812 may be oxidized, thereby forming an oxidized layer 814. The oxidized layer 814 may substantially consist of a metal oxide. It is understood that the metal of the metal nitride may be the metal of the metal oxide. In 804C, the oxidized layer 814 may be chemically reduced, thereby forming a reduced layer 816. This reduced layer 816 may substantially consist of the metal and therefore provide the metal layer (e.g., the second electrically conductive electrode layer 136).

As detailed herein, when growing a (pure) metal layer via ALD, the metal may show a severely delayed or even no nucleation on oxides. In some cases, the metal may even etch a surface of the oxide layer. An example of such a metal is tungsten which may be deposited using a halide based or a metalorganic based tungsten precursor. For example, the halide based tungsten precursor may be tungsten fluoride (WF₆) which leads to an etching of the surface of the oxide layer. In the case of tungsten, it is therefore impossible to grow a tungsten layer directly on an oxide layer via ALD. According to various aspects, a method is provided which uses a metal nitride or metal oxynitride layer as a nucleation layer to grow the metal, such as tungsten, over an oxide layer. Besides serving as a nucleation layer, the metal nitride or metal oxynitride layer may also protect the oxide layer from possible damage (e.g., during ALD using tungsten fluoride). In some aspects, at least a part of the first functional layer 134 and/or the second functional layer 138 may be etched during the ALD of the first electrically conductive electrode layer 132 and/or second electrically conductive electrode layer 136, respectively (e.g., when using tungsten fluoride as precursor).

In an experimental investigation, a first functional layer 134 substantially consisting of titanium nitride was formed directly on a silicon wafer having a natural silicon oxide surface layer. Subsequently, a first electrically conductive electrode layer 132 layer substantially consisting of tungsten was formed directly on the first functional layer 134 by CVD (the first electrically conductive electrode layer 132 having a thickness of about 50 nm). Subsequently, a memory element 124 substantially consisting of HZO (and having a thickness of about 10 nm) was formed directly on the first electrically conductive electrode layer 132. The experiments revealed that the first electrically conductive electrode layer 132 substantially consisting of tungsten can be formed directly on the titanium nitride of the first functional layer 134. An ALD process using tungsten fluoride as precursor was carried out corresponding to about 10 nm of tungsten. In some experiments, no second functional layer 138 was formed prior to this ALD process; in this case, no tungsten was deposited on the memory element 124 but the ALD process led to an etching of the HZO. In other experiments, a second functional layer 138 having a thickness of about 1 nm and substantially consisting of titanium nitride was formed directly on the memory element 124 prior to the ALD process; in this case, the titanium nitride of the second functional layer 138 was etched away after the ALD process. In some regions, the thickness of the second functional layer 138 was greater than 1 nm; in these regions, tungsten adhered on the HZO. In even other experiments, a second functional layer 138 having a thickness greater than 1 nm and substantially consisting of titanium nitride was formed directly on the memory element 124 prior to the ALD process; in this case, the titanium nitride of the second functional layer 138 served as a nucleation/adhesion layer and the ALD process led to the second electrically conductive electrode layer 136 having a thickness of about 10 nm and substantially consisting of tungsten. Still, in some aspects, at least a portion of the second functional layer 138 may be etched during the ALD process. Thus, the second functional layer 138 may also serve as a sacrificial layer.

According to various aspects, a method is provided which allows to generate a metal layer directly on an oxide layer by first depositing a metal nitride layer, oxidizing the metal nitride to a metal oxide, and then reducing the metal oxide to the metal.

In the following, various examples are provided that may include one or more aspects described above with reference to a memory cell including the SPOC structure 120, to a memory cell arrangement including at least one such memory cell, and to the methods described herein. It may be intended that aspects described in relation to one or more of the methods may apply also to the memory cell and/or memory cell arrangement, and vice versa. For example, a method may include at least a part of the formation of the SPOC structure 120.

Example 1 is a memory cell including: a substrate portion; and a memory layer stack disposed over (e.g., conformally covering) the substrate portion, the memory layer stack including: a first electrode disposed over the substrate portion; a memory element disposed over the first electrode, the memory element including a spontaneously polarizable material; and a second electrode disposed over the memory element, wherein the first electrode, the second electrode, and the memory element form a memory capacitor; wherein the first electrode includes a first electrically conductive electrode layer substantially consisting of a first metal (e.g., tungsten) and a first functional layer substantially consisting of a first metal nitride (e.g., tungsten nitride or titanium nitride) or a first metal-oxynitride, wherein the first electrically conductive electrode layer is disposed between the first functional layer and the memory element and wherein the first electrically conductive electrode layer is disposed in direct contact with the first functional layer, and/or wherein the second electrode includes a second electrically conductive electrode layer substantially consisting of a second metal (e.g., tungsten) and a second functional layer substantially consisting of a second metal nitride (e.g., tungsten nitride or titanium nitride) or a second metal-oxynitride, wherein the second functional layer is disposed between the memory element and the second electrically conductive electrode layer and wherein the second functional layer is disposed in direct contact with the memory element and the second electrically conductive electrode layer.

In Example 2, the subject matter of Example 1 can optionally include that the substrate portion includes a three-dimensional structure.

In Example 3, the subject matter of Example 2 can optionally include that the memory layer stack is disposed over (e.g., conformally covering) the three-dimensional structure.

In Example 4, the subject matter of Example 2 or 3 can optionally include that the memory layer stack is disposed conformally over the three-dimensional structure. In some aspects, only some layers of the memory layer stack may conformally cover a layer disposed below a respective one of these layers. For example, the first electrically conductive electrode may conformally cover the first functional layer and/or the second electrically conductive electrode may conformally cover the second functional layer.

In Example 5, the subject matter of any one of Examples 2 to 4 can optionally include that the three-dimensional structure has an aspect ratio equal to or greater than six (e.g., equal to or greater than ten, e.g., equal to or greater than fifteen, e.g., equal to or greater than twenty, etc.) and/or that the three-dimensional structure has a width (e.g., an opening width) equal to or less than 200 nm (e.g., equal to or less than 100 nm, e.g., equal to or less than 50 nm, etc.).

In Example 6, the subject matter of any one of Examples 2 to 5 can optionally include that the three-dimensional structure includes at least one of a trench, a cup, a nanowire, nanoparticles, or a surface of a porous material.

In Example 7, the subject matter of any one of Examples 1 to 6 can optionally include that the substrate portion includes an (e.g., natural or artificial) oxide layer at its interface to the memory layer stack, wherein the first functional layer is disposed between and in direct contact with the oxide layer and the first electrically conductive electrode layer.

In Example 8, the subject matter of Example 7 can optionally include that the oxide layer substantially consists of a low-k material.

In Example 9, the subject matter of Example 7 or 8 can optionally include that the oxide layer substantially consists of silicon oxide.

In Example 10, the subject matter of any one of Examples 2 to 6 in combination with any one of Examples 7 to 9 can optionally include that the three-dimensional structure is a trench disposed within the oxide layer; or that the oxide layer is disposed (e.g., conformally) over the three-dimensional structure.

In Example 11, the subject matter of any one of Examples 1 to 10 can optionally include that the spontaneously polarizable material of the memory element substantially consists of one or more transition-metal-oxides.

In Example 12, the subject matter of any one of Examples 1 to 11 can optionally include that the spontaneously polarizable material of the memory element is a remanent-polarizable material.

In Example 13, the subject matter of any one of Examples 1 to 12 can optionally include that the spontaneously polarizable material of the memory element is hafnium oxide, zirconium oxide, or hafnium zirconium oxide.

In Example 14, the subject matter of any one of Examples 1 to 13 can optionally include that the first metal and/or the second metal is tungsten.

In Example 15, the subject matter of any one of Examples 1 to 14 can optionally include that the first metal nitride and/or the second metal nitride is tungsten nitride.

In Example 16, the subject matter of any one of Examples 1 to 15 can optionally include that the first metal-oxynitride and/or the second metal-oxynitride is tungsten-oxynitride.

In Example 17, the subject matter of any one of Examples 1 to 16 can optionally include that the first metal is a same metal as a metal of the first metal nitride or first metal-oxynitride; or wherein the first metal is different from a metal of the first metal nitride or first metal-oxynitride.

In Example 18, the subject matter of any one of Examples 1 to 17 can optionally include that the second metal is a same metal as the metal of the second metal nitride or second metal-oxynitride; or wherein the second metal is different from a metal of the second metal nitride or second metal-oxynitride.

In Example 19, the subject matter of any one of Examples 1 to 18 can optionally include that the first metal and the second metal are a same metal; or wherein the first metal and the second metal are different metals.

In Example 20, the subject matter of any one of Examples 1 to 19 can optionally include that the first functional layer and/or the second functional layer has a thickness greater than 1 nm, optionally in a range from about 1.1 nm to about 5 nm. Additionally or alternatively, the first electrically conductive electrode layer and/or the second electrically conductive electrode layer may have a thickness in a range from about 1 nm to about 5 nm.

In Example 21, the subject matter of any one of Examples 1 to 20 can optionally include that the first metal nitride and/or the second metal nitride is one of: titanium nitride (TiN), tungsten nitride (WN), molybdenum nitride (MoN), tantalum nitride (TaN), niobium nitride (NbN), hafnium nitride (HfN), or zirconium nitride (ZrN).

In Example 22, the subject matter of any one of Examples 1 to 21 can optionally include that the first electrode further includes a further first functional layer substantially consisting of the first metal nitride or the first metal-oxynitride, wherein the further first functional layer is disposed between and in direct contact with the memory element and the first electrically conductive electrode layer.

In Example 23, the subject matter of any one of Examples 1 to 22 can optionally include that the second electrode further includes a further second functional layer substantially consisting of the second metal nitride or the second metal-oxynitride, wherein the further second functional layer is disposed directly on the second electrically conductive electrode layer.

Example 24 is a (e.g., DRAM) memory cell arrangement including: a plurality of memory cells, wherein at least one (e.g., each) memory cell of the plurality of memory cells is configured in accordance with the memory cell of any one of Examples 1 to 23; a substrate including the substrate portion(s) of the at least one (e.g., each) memory cell; and a plurality of sets of control lines for selectively addressing one or more memory cells of the plurality of memory cells.

Example 25 is a method including: forming a memory layer stack over a substrate portion by: forming a first electrode over the substrate portion; forming a memory element over the first electrode (e.g., using atomic layer deposition), the memory element including a spontaneously polarizable material; and forming a second electrode over the memory element, wherein the first electrode, the second electrode, and the memory element form a memory capacitor; wherein forming the first electrode includes forming a first functional layer substantially consisting of a first metal nitride or a first metal-oxynitride (e.g., using atomic layer deposition) and (e.g., conformally) forming a first electrically conductive electrode layer substantially consisting of a first metal directly on the first functional layer using atomic layer deposition, and/or wherein forming the second electrode includes forming a second functional layer substantially consisting of a second metal nitride or a second metal-oxynitride directly on the memory element (e.g., using atomic layer deposition) and (e.g., conformally) forming a second electrically conductive electrode layer substantially consisting of a second metal directly on the second functional layer using atomic layer deposition.

In Example 26, the subject matter of Example 25 can optionally include that forming the first functional layer substantially consisting of the first metal nitride includes forming the first functional layer by atomic layer deposition using a metal-organic precursor or a halide precursor.

In Example 27, the subject matter of Example 26 can optionally include that the metal organic precursor includes the metal of the metal nitride and optionally nitrogen.

In Example 28, the subject matter of Example 26 or 27 can optionally include that forming the first functional layer includes forming the first functional layer by atomic layer deposition using the metal-organic precursor or the halide precursor and a reducing and/or nitrogenating agent.

In Example 29, the subject matter of Example 26 or 28 can optionally include that the first metal is tungsten and the halide precursor includes tungsten fluoride.

In Example 30, the subject matter of any one of Examples 25 to 29 can optionally include that forming the second functional layer substantially consisting of the second metal nitride includes forming the second functional layer by atomic layer deposition using a metal-organic precursor or a halide precursor.

In Example 31, the subject matter of Example 30 can optionally include that the metal organic precursor includes the metal of the metal nitride and optionally nitrogen.

In Example 32, the subject matter of Example 30 or 31 can optionally include that forming the second functional layer includes forming the second functional layer by atomic layer deposition using the metal-organic precursor or the halide precursor and a reducing and/or nitrogenating agent.

In Example 33, the subject matter of any one of Examples 30 to 32 can optionally include that the second metal is tungsten and the halide precursor includes tungsten fluoride

In Example 34, the subject matter of any one of Examples 25 to 33 can optionally include that forming the first functional layer substantially consisting of the first metal-oxynitride and/or forming the second functional layer substantially consisting of the second metal-oxynitride includes: forming a layer substantially consisting of a metal nitride using atomic layer deposition, the metal nitride including the metal of the metal-oxynitride; and oxidizing the metal nitride of the layer to thereby form the (e.g., highly oxidized) metal-oxynitride.

In Example 35, the subject matter of Example 34 can optionally include that forming the layer substantially consisting of the metal nitride includes forming the layer by atomic layer deposition using a metal-organic precursor or a halide precursor.

In Example 36, the subject matter of Example 35 can optionally include that the metal organic precursor includes the metal of the metal nitride and optionally nitrogen.

In Example 37, the subject matter of Example 35 or 36 can optionally include that forming the layer by atomic layer deposition includes forming the layer by atomic layer deposition using the metal-organic precursor or the halide precursor and a reducing and/or nitrogenating agent.

In Example 38, the subject matter of any one of Examples 25 to 37 can optionally include that the substrate portion includes a three-dimensional structure.

In Example 39, the subject matter of Example 38 can optionally include that the memory layer stack is formed over the three-dimensional structure.

In Example 40, the subject matter of Example 39 can optionally include that the memory layer stack is formed conformally over the three-dimensional structure.

In Example 41, the subject matter of any one of Examples 38 to 40 can optionally include that the three-dimensional structure includes a trench.

In Example 42, the subject matter of Example 41 can optionally include that the trench has an aspect ratio equal to or greater than six (e.g., equal to or greater than ten, e.g., equal to or greater than fifteen, e.g., equal to or greater than twenty, etc.).

In Example 43, the subject matter of any one of Examples 40 to 42 can optionally include that the three-dimensional structure includes at least one of a trench, a cup, a nanowire, nanoparticles, or a surface of a porous material.

In Example 44, the subject matter of any one of Examples 25 to 43 can optionally include that the substrate portion includes an (e.g., natural or artificial) oxide layer at its interface to the memory layer stack, wherein the first functional layer is disposed between and in direct contact with the oxide layer and the first electrically conductive electrode layer.

In Example 45, the subject matter of Example 44 can optionally include that the oxide layer substantially consists of a low-k material.

In Example 46, the subject matter of Example 44 or 45 can optionally include that the oxide layer substantially consists of silicon oxide.

In Example 37, the subject matter of any one of Examples 38 to 43 in combination with any one of Examples 44 to 46 can optionally further include: etching the substrate portion to form the trench and forming the oxide layer conformally at least within the trench.

In Example 38, the subject matter of any one of Examples 38 to 43 in combination with any one of Examples 44 to 46 can optionally further include: etching the oxide layer to form the trench within the oxide layer.

In Example 49, the subject matter of any one of Examples 25 to 48 can optionally include that the spontaneously polarizable material of the memory element is an oxide material, e.g., that the spontaneously polarizable material substantially consists of one or more transition-metal-oxides.

In Example 50, the subject matter of any one of Examples 25 to 49 can optionally include that the spontaneously polarizable material of the memory element is a remanent-polarizable material.

In Example 51, the subject matter of any one of Examples 25 to 50 can optionally include that the spontaneously polarizable material of the memory element is hafnium oxide, zirconium oxide, or hafnium zirconium oxide.

In Example 52, the subject matter of any one of Examples 25 to 51 can optionally include that the first metal and/or the second metal is tungsten.

In Example 53, the subject matter of any one of Examples 25 to 52 can optionally include that the first metal nitride and/or the second metal nitride is tungsten nitride.

In Example 54, the subject matter of any one of Examples 25 to 53 can optionally include that the first metal-oxynitride and/or the second metal-oxynitride is tungsten-oxynitride.

In Example 55, the subject matter of any one of Examples 25 to 54 can optionally include that the first metal is a same metal as a metal of the first metal nitride or first metal-oxynitride; or wherein the first metal is different from a metal of the first metal nitride or first metal-oxynitride.

In Example 56, the subject matter of any one of Examples 25 to 55 can optionally include that the second metal is a same metal as the metal of the second metal nitride or second metal-oxynitride; or wherein the second metal is different from a metal of the second metal nitride or second metal-oxynitride.

In Example 57, the subject matter of any one of Examples 25 to 56 can optionally include that the first metal and the second metal are a same metal; or wherein the first metal and the second metal are different metals.

In Example 58, the subject matter of any one of Examples 25 to 57 can optionally include that the first functional layer and/or the second functional layer has a thickness greater than 1 nm, optionally in a range from about 1.1 nm to about 5 nm. Additionally or alternatively, the first electrically conductive electrode layer and/or the second electrically conductive electrode layer may have a thickness in a range from about 1 nm to about 5 nm.

In Example 59, the subject matter of any one of Examples 25 to 58 can optionally include that the first metal nitride and/or the second metal nitride is one of: titanium nitride (TiN), tungsten nitride (WN), molybdenum nitride (MoN), tantalum nitride (TaN), niobium nitride (NbN), hafnium nitride (HfN), or zirconium nitride (ZrN).

In Example 60, the subject matter of any one of Examples 25 to 59 can optionally include that forming the first electrode further includes forming a further first functional layer substantially consisting of the first metal nitride or the first metal-oxynitride directly on the first electrically conductive electrode layer prior to forming memory element.

In Example 61, the subject matter of any one of Examples 25 to 60 can optionally include that forming the second electrode further includes forming a further second functional layer substantially consisting of the second metal nitride or the second metal-oxynitride directly on the second electrically conductive electrode layer.

Example 62 is a method of forming a (e.g., DRAM) memory cell arrangement, the method including: simultaneously forming a plurality of memory cells over a respective substrate portion of a substrate in accordance with the method of any one of Examples 25 to 61.

In Example 63, the method of Example 62 can optionally further include: forming a plurality of sets of control lines for selectively addressing one or more memory cells of the plurality of memory cells.

Example 64 is a memory cell including: a substrate portion; and a memory layer stack disposed over (e.g., conformally covering) the substrate portion, the memory layer stack including: a first electrode disposed over the substrate portion; a memory element disposed over the first electrode, the memory element including a spontaneously polarizable material; and a second electrode disposed over the memory element, wherein the first electrode, the second electrode, and the memory element form a memory capacitor; wherein the first electrode includes a first electrically conductive electrode layer substantially consisting of a first metal and a first functional layer stack, the first functional layer stack including a first functional layer substantially consisting of a first metal oxide and a further first functional layer substantially consisting of a first metal nitride or a first metal-oxynitride, wherein the further first functional layer is disposed between the first functional layer and the first electrically conductive electrode layer and in direct contact with the first electrically conductive electrode layer, and/or wherein the second electrode includes a second electrically conductive electrode layer substantially consisting of a first metal and a second functional layer stack, the second functional layer stack including a second functional layer substantially consisting of a second metal oxide and a further second functional layer substantially consisting of a second metal nitride or a second metal-oxynitride, wherein the second functional layer is disposed directly on the memory element, and wherein the further second functional layer is disposed between and in direct contact with the second functional layer and the second electrically conductive electrode layer.

In Example 65, the subject matter of Example 64 can optionally include that the substrate portion includes a three-dimensional structure.

In Example 66, the subject matter of Example 65 can optionally include that the memory layer stack is disposed over (e.g., conformally covering) the three-dimensional structure.

In Example 67, the subject matter of Example 66 can optionally include that the memory layer stack is disposed conformally over the three-dimensional structure. . . . In some aspects, only some layers of the memory layer stack may conformally cover a layer disposed below a respective one of these layers. For example, the first electrically conductive electrode may conformally cover the first functional layer and/or the second electrically conductive electrode may conformally cover the second functional layer.

In Example 68, the subject matter of any one of Examples 65 to 67 can optionally include that the three-dimensional structure has an aspect ratio equal to or greater than six (e.g., equal to or greater than ten, e.g., equal to or greater than fifteen, e.g., equal to or greater than twenty, etc.) and/or that the three-dimensional structure has a width (e.g., an opening width) equal toor less than 200 nm (e.g., equal to or less than 100 nm, e.g., equal to or less than 50 nm, etc.).

In Example 69, the subject matter of any one of Examples 65 to 68 can optionally include that the three-dimensional structure includes at least one of a trench, a cup, a nanowire, nanoparticles, or a surface of a porous material.

In Example 70, the subject matter of any one of Examples 64 to 69 can optionally include that the substrate portion includes an (e.g., natural or artificial) oxide layer at its interface to the memory layer stack, wherein the first functional layer is disposed between and in direct contact with the oxide layer and the first electrically conductive electrode layer.

In Example 71, the subject matter of Example 70 can optionally include that the oxide layer substantially consists of a low-k material.

In Example 72, the subject matter of Example 70 or 71 can optionally include that the oxide layer substantially consists of silicon oxide.

In Example 73, the subject matter of any one of Examples 65 to 69 in combination with any one of Examples 70 to 72 can optionally include that the three-dimensional structure is a trench disposed within the oxide layer; or wherein the oxide layer is disposed (e.g., conformally) over the three-dimensional structure.

In Example 74, the subject matter of any one of Examples 64 to 73 can optionally include that the spontaneously polarizable material of the memory element an oxide material (e.g., which substantially consists of one or more transition-metal-oxides).

In Example 75, the subject matter of any one of Examples 64 to 74 can optionally include that the spontaneously polarizable material of the memory element is a remanent-polarizable material.

In Example 76, the subject matter of any one of Examples 64 to 75 can optionally include that the spontaneously polarizable material of the memory element is hafnium oxide, zirconium oxide, or hafnium zirconium oxide.

In Example 77, the subject matter of any one of Examples 64 to 76 can optionally include that the first metal and/or the second metal is tungsten.

In Example 78, the subject matter of any one of Examples 64 to 77 can optionally include that the first metal nitride and/or the second metal nitride is tungsten nitride.

In Example 79, the subject matter of any one of Examples 64 to 78 can optionally include that the first metal-oxynitride and/or the second metal-oxynitride is tungsten-oxynitride.

In Example 80, the subject matter of any one of Examples 64 to 79 can optionally include that the first metal is a same metal as a metal of the first metal nitride or first metal-oxynitride; or wherein the first metal is different from a metal of the first metal nitride or first metal-oxynitride.

In Example 81, the subject matter of any one of Examples 64 to 80 can optionally include that the second metal is a same metal as the metal of the second metal nitride or second metal-oxynitride; or wherein the second metal is different from a metal of the second metal nitride or second metal-oxynitride.

In Example 82, the subject matter of any one of Examples 64 to 81 can optionally include that the first metal and the second metal are a same metal; or wherein the first metal and the second metal are different metals.

In Example 83, the subject matter of any one of Examples 64 to 82 can optionally include that the first functional layer and/or the second functional layer has a thickness greater than 1 nm, optionally in a range from about 1.1 nm to about 5 nm. Additionally or alternatively, the first electrically conductive electrode layer and/or the second electrically conductive electrode layer may have a thickness in a range from about 1 nm to about 5 nm.

In Example 84, the subject matter of any one of Examples 64 to 83 can optionally include that the first metal nitride and/or the second metal nitride is one of: titanium nitride (TiN), tungsten nitride (WN), molybdenum nitride (MoN), tantalum nitride (TaN), niobium nitride (NbN), hafnium nitride (HfN), or zirconium nitride (ZrN).

In Example 85, the subject matter of any one of Examples 64 to 84 can optionally include that the first electrode further includes a further first functional layer substantially consisting of the first metal nitride or the first metal-oxynitride, wherein the further first functional layer is disposed between and in direct contact with the memory element and the first electrically conductive electrode layer.

In Example 86, the subject matter of any one of Examples 64 to 85 can optionally include that the second electrode further includes a further second functional layer substantially consisting of the second metal nitride or the second metal-oxynitride, wherein the further second functional layer is disposed directly on the second electrically conductive electrode layer.

Example 87 is a (e.g., DRAM) memory cell arrangement including: a plurality of memory cells, wherein at least one (e.g., each) memory cell of the plurality of memory cells is configured in accordance with the memory cell of any one of Examples 64 to 86; a substrate including the substrate portion(s) of the at least one (e.g., each) memory cell; and a plurality of sets of control lines for selectively addressing one or more memory cells of the plurality of memory cells.

Example 88 is a method including: forming a memory layer stack over a substrate portion by: forming a first electrode over the substrate portion; forming a memory element over the first electrode using atomic layer deposition, the memory element including a spontaneously polarizable material; and forming a second electrode over the memory element, wherein the first electrode, the second electrode, and the memory element form a memory capacitor; wherein forming the first electrode includes forming a first functional layer stack and forming a first electrically conductive electrode layer substantially consisting of a first metal directly on the first functional layer stack using atomic layer deposition, wherein forming the first functional layer stack includes forming a first functional layer substantially consisting of a first metal oxide and forming a further first functional layer substantially consisting of a first metal nitride or a first metal-oxynitride, and/or wherein forming the second electrode includes forming a second functional layer stack directly on the memory element and forming a second electrically conductive electrode layer substantially consisting of a second metal directly on the second functional layer stack using atomic layer deposition, wherein forming the second functional layer stack includes forming a second functional layer substantially consisting of a second metal oxide and forming a further second functional layer substantially consisting of a second metal nitride or a second metal-oxynitride.

In Example 89, the subject matter of Example 88 can optionally include that forming the first functional layer substantially consisting of the first metal nitride includes forming the first functional layer by atomic layer deposition (e.g., using a metal-organic precursor or a halide precursor).

In Example 90, the subject matter of Example 89 can optionally include that the metal organic precursor includes the metal of the metal nitride and optionally nitrogen.

In Example 91, the subject matter of Example 89 or 90 can optionally include that forming the first functional layer by atomic layer deposition includes forming the first functional layer by atomic layer deposition using the metal-organic precursor or the halide precursor and a reducing and/or nitrogenating agent.

In Example 92, the subject matter of any one of Examples 89 to 91 can optionally include that the first metal is tungsten and the halide precursor includes tungsten fluoride.

In Example 93, the subject matter of any one of Examples 88 to 92 can optionally include that forming the second functional layer substantially consisting of the second metal nitride includes forming the second functional layer by atomic layer deposition (e.g., using a metal-organic precursor or a halide precursor).

In Example 94, the subject matter of Example 93 can optionally include that the metal organic precursor includes the metal of the metal nitride and optionally nitrogen.

In Example 95, the subject matter of Example 93 or 94 can optionally include that forming the second functional layer by atomic layer deposition includes forming the second functional layer by atomic layer deposition using the metal-organic precursor or the halide precursor and a reducing and/or nitrogenating agent.

In Example 96, the subject matter of any one of Examples 93 to 95 can optionally include that the second metal is tungsten and the halide precursor includes tungsten fluoride

In Example 97, the subject matter of any one of Examples 88 to 96 can optionally include that forming the first functional layer substantially consisting of the first metal-oxynitride and/or forming the second functional layer substantially consisting of the second metal-oxynitride includes: forming a layer substantially consisting of a metal nitride using atomic layer deposition, the metal nitride including the metal of the metal-oxynitride; and oxidizing the metal nitride of the layer to thereby form the (e.g., highly oxidized) metal-oxynitride.

In Example 98, the subject matter of Example 97 can optionally include that forming the layer substantially consisting of the metal nitride includes forming the layer by atomic layer deposition using a metal-organic precursor or a halide precursor.

In Example 99, the subject matter of Example 98 can optionally include that the metal organic precursor includes the metal of the metal nitride and optionally nitrogen.

In Example 100, the subject matter of Example 98 or 99 can optionally include that forming the layer by atomic layer deposition includes forming the layer by atomic layer deposition using the metal-organic precursor or the halide precursor and a reducing and/or nitrogenating agent.

In Example 101, the subject matter of any one of Examples 88 to 100 can optionally include that the substrate portion includes a three-dimensional structure.

In Example 102, the subject matter of Example 101 can optionally include that the memory layer stack is formed over the three-dimensional structure.

In Example 103, the subject matter of Example 102 can optionally include that at least part of the memory layer stack is formed conformally over the three-dimensional structure.

In Example 104, the subject matter of any one of Examples 101 to 103 can optionally include that the three-dimensional structure includes a trench.

In Example 105, the subject matter of Example 104 can optionally include that the trench has an aspect ratio equal to or greater than six (e.g., equal to or greater than ten, e.g., equal to or greater than fifteen, e.g., equal to or greater than twenty, etc.).

In Example 106, the subject matter of any one of Examples 103 to 105 can optionally include that the three-dimensional structure includes at least one of a trench, a cup, a nanowire, nanoparticles, or a surface of a porous material.

In Example 107, the subject matter of any one of Examples 88 to 106 can optionally include that the substrate portion includes an (e.g., natural or artificial) oxide layer at its interface to the memory layer stack, wherein the first functional layer is disposed between and in direct contact with the oxide layer and the first electrically conductive electrode layer.

In Example 108, the subject matter of Example 107 can optionally include that the oxide layer substantially consists of a low-k material.

In Example 109, the subject matter of Example 107 or 108 can optionally include that the oxide layer substantially consists of silicon oxide.

In Example 110, the subject matter of any one of Examples 101 to 106 in combination with any one of Examples 107 to 109 can optionally further include: etching the substrate portion to form the trench and forming the oxide layer conformally at least within the trench.

In Example 111, the subject matter of any one of Examples 101 to 106 in combination with any one of Examples 107 to 109 can optionally further include: etching the oxide layer to form the trench within the oxide layer.

In Example 112, the subject matter of any one of Examples 88 to 111 can optionally include that the spontaneously polarizable material of the memory element is an oxide material (e.g., which substantially consists of one or more transition-metal-oxides).

In Example 113, the subject matter of any one of Examples 88 to 112 can optionally include that the spontaneously polarizable material of the memory element is a remanent-polarizable material.

In Example 114, the subject matter of any one of Examples 88 to 113 can optionally include that the spontaneously polarizable material of the memory element is hafnium oxide, zirconium oxide, or hafnium zirconium oxide.

In Example 115, the subject matter of any one of Examples 88 to 114 can optionally include that the first metal and/or the second metal is tungsten.

In Example 116, the subject matter of any one of Examples 88 to 115 can optionally include that the first metal nitride and/or the second metal nitride is tungsten nitride.

In Example 117, the subject matter of any one of Examples 88 to 116 can optionally include that the first metal-oxynitride and/or the second metal-oxynitride is tungsten-oxynitride.

In Example 118, the subject matter of any one of Examples 88 to 117 can optionally include that the first metal is a same metal as a metal of the first metal nitride or first metal-oxynitride; or wherein the first metal is different from a metal of the first metal nitride or first metal-oxynitride.

In Example 119, the subject matter of any one of Examples 88 to 118 can optionally include that the second metal is a same metal as the metal of the second metal nitride or second metal-oxynitride; or wherein the second metal is different from a metal of the second metal nitride or second metal-oxynitride.

In Example 120, the subject matter of any one of Examples 88 to 119 can optionally include that the first metal and the second metal are a same metal; or wherein the first metal and the second metal are different metals.

In Example 121, the subject matter of any one of Examples 88 to 120 can optionally include that the first functional layer and/or the second functional layer has a thickness greater than 1 nm, optionally in a range from about 1.1 nm to about 5 nm. Additionally or alternatively, the first electrically conductive electrode layer and/or the second electrically conductive electrode layer may have a thickness in a range from about 1 nm to about 5 nm.

In Example 122, the subject matter of any one of Examples 151 to 121 can optionally include that the first metal nitride and/or the second metal nitride is one of: titanium nitride (TiN), tungsten nitride (WN), molybdenum nitride (MoN), tantalum nitride (TaN), niobium nitride (NbN), hafnium nitride (HfN), or zirconium nitride (ZrN).

In Example 123, the subject matter of any one of Examples 151 to 122 can optionally include that forming the first electrode further includes forming a further first functional layer substantially consisting of the first metal nitride or the first metal-oxynitride directly on the first electrically conductive electrode layer prior to forming memory element.

In Example 124, the subject matter of any one of Examples 151 to 123 can optionally include that forming the second electrode further includes forming a further second functional layer substantially consisting of the second metal nitride or the second metal-oxynitride directly on the second electrically conductive electrode layer.

Example 125 is a method of forming a (e.g., DRAM) memory cell arrangement, the method including: simultaneously forming a plurality of memory cells over a respective substrate portion of a substrate in accordance with the method of any one of Examples 88 to 124.

In Example 126, the method of Example 125 can optionally further include: forming a plurality of sets of control lines for selectively addressing one or more memory cells of the plurality of memory cells.

Example 127 is a memory cell including: a substrate portion; and a memory layer stack disposed over (e.g., conformally covering) the substrate portion, the memory layer stack including: a first electrode disposed over the substrate portion; a memory element disposed over the first electrode, the memory element including a spontaneously polarizable material, wherein the spontaneously polarizable material substantially consists of spontaneously polarizable one or more transition-metal-oxides; a second electrode disposed over the memory element, wherein the first electrode, the second electrode, and the memory element form a memory capacitor; and a functional layer disposed between and in direct contact with the memory element and the second electrode, wherein the functional layer substantially consists of a suboxide of the one or more transition-metal-oxides or of a transition metal of the one or more transition-metal-oxides.

In Example 128, the subject matter of Example 127 can optionally include that the one or more transition-metal-oxides have a first oxygen content and wherein the suboxide of the one or more transition-metal-oxides has a second oxygen content less than the first oxygen content.

The memory cell of Example 127 or Example 128 may be, where applicable, configured in accordance with the memory cell of any one of Examples 1 to 24, 64 to 87.

Example 129 is a method including: forming a memory layer stack over a substrate portion by: forming a first electrode over the substrate portion (e.g., using atomic layer deposition); forming a memory element over the first electrode (e.g., using atomic layer deposition), the memory element including a spontaneously polarizable material, wherein the spontaneously polarizable material substantially consists of spontaneously polarizable one or more transition-metal-oxides; reducing a surface layer of the memory element to thereby form a functional layer which substantially consists of a suboxide of the one or more transition-metal-oxides or of a transition metal of the one or more transition-metal-oxides; and forming a second electrode directly on the functional layer (e.g., using atomic layer deposition), wherein the first electrode, the second electrode, and the memory element form a memory capacitor;

In Example 130, the subject matter of Example 129 can optionally include that the one or more transition-metal-oxides have a first oxygen content and wherein the suboxide of the one or more transition-metal-oxides has a second oxygen content less than the first oxygen content.

The method of Example 129 or Example 130 may be, where applicable, configured in accordance with the method of any one of Examples 25 to 63, 88 to 126.

Example 131 is a method including: forming an oxide layer; forming an electrode layer substantially consisting of a metal directly on the oxide layer by: forming a layer substantially consisting of a metal nitride (or a metalloid nitride) directly on the oxide layer, oxidizing the metal (or metalloid) nitride of the layer such that the layer substantially consists of a metal (or metalloid) oxide, and reducing the metal (or metalloid) oxide of the layer to the metal to thereby form the electrode layer.

In Example 132, the subject matter of Example 131 can optionally include that the oxide layer substantially consists of one of: a metal oxide, a metalloid oxide, or one or more transition-metal-oxides.

In Example 133, the subject matter of Example 131 or 132 can optionally include that forming the layer substantially consisting of the metal nitride (or the metalloid nitride) directly on the oxide layer includes forming the layer substantially consisting of the metal nitride (or the metalloid nitride) directly on the oxide layer using atomic layer deposition.

The method of any one of Examples 131 to 133 may be, where applicable, configured in accordance with the method of any one of Examples 25 to 63, 88 to 126.

Example 134 is a memory cell arrangement including: a substrate including a plurality of three-dimensional structures; a plurality of memory cells; and a plurality of sets of control lines for selectively addressing one or more memory cells of the plurality of memory cells; wherein each memory cell of the plurality of memory cells includes a memory layer stack (e.g., conformally covering) a respective three-dimensional structure of the plurality of three-dimensional structures, the memory layer stack including: a first electrode; a memory element disposed over the first electrode; and a second electrode disposed over the memory element, wherein the first electrode, the second electrode, and the memory element form a memory capacitor; and (i) wherein the substrate includes an oxide layer at its interface to the memory layer stack and wherein the first electrode includes a first electrically conductive electrode layer substantially consisting of a first metal (e.g., tungsten) and a first functional layer substantially consisting of a first metal nitride (e.g., tungsten nitride or titanium nitride) or a first metal-oxynitride, wherein the first electrically conductive electrode layer is disposed between the first functional layer and the memory element and in direct contact with the first functional layer; and/or (ii) wherein the memory element substantially consists of one or more spontaneously polarizable transition-metal-oxides and wherein the second electrode includes a second electrically conductive electrode layer substantially consisting of a second metal (e.g., tungsten) and a second functional layer substantially consisting of a second metal nitride (e.g., tungsten nitride or titanium nitride) or a second metal-oxynitride, wherein the second functional layer is disposed between the memory element and the second electrically conductive electrode layer and in direct contact with the memory element.

In Example 135, the subject matter of Example 134 can optionally include that the respective three-dimensional structure includes at least one of a trench, a cup, a nanowire, nanoparticles, or a surface of a porous material.

In Example 136, the subject matter of Example 134 or 135 can optionally include that the first electrically conductive electrode conformally covers the first functional layer and/or that the second electrically conductive electrode conformally covers the second functional layer. Optionally, the memory layer stack may conformally cover the respective three-dimensional structure. As described herein, a layer conformally covering a prior layer within a three-dimensional structure may indicate that the layer is formed by atomic layer deposition.

In Example 137, the subject matter of any one of Examples 134 to 136 can optionally include that the respective three-dimensional structure has an aspect ratio equal to or greater than six and/or a width equal to or less than 200 nm (e.g., equal to or less than 100 nm, e.g., equal to or less than 50 nm, etc.).

In Example 138, the subject matter of any one of Examples 134 to 137 can optionally include that the oxide layer substantially consists of a low-k material.

In Example 139, the subject matter of Example 138 can optionally include that the respective three-dimensional structure is a trench disposed within the oxide layer or wherein the respective three-dimensional structure is a trench disposed within the substrate and conformally covered with one or more oxide layers.

In Example 140, the subject matter of any one of Examples 134 to 139 can optionally include that the one or more transition-metal-oxides of the memory element are hafnium oxide, zirconium oxide, or hafnium zirconium oxide.

In Example 141, the subject matter of any one of Examples 134 to 140 can optionally include that the first metal nitride and/or the second metal nitride is tungsten nitride; and/or wherein the first metal-oxynitride and/or the second metal-oxynitride is tungsten-oxynitride.

In Example 142, the subject matter of any one of Examples 134 to 141 can optionally include that the first functional layer and/or the second functional layer has a thickness greater than 1 nm.

In Example 143, the subject matter of any one of Examples 134 to 142 can optionally include that the first metal nitride and/or the second metal nitride is one of: titanium nitride, tungsten nitride, molybdenum nitride, tantalum nitride, niobium nitride, hafnium nitride, or zirconium nitride.

In Example 144, the subject matter of any one of Examples 134 to 143 can optionally include that the first electrode further includes a further first functional layer substantially consisting of the first metal nitride or the first metal-oxynitride, wherein the further first functional layer is disposed between and in direct contact with the memory element and the first electrically conductive electrode layer; and/or wherein the second electrode further includes a further second functional layer substantially consisting of the second metal nitride or the second metal-oxynitride, wherein the further second functional layer is disposed directly on the second electrically conductive electrode layer.

Example 145 is a method including: forming a memory layer stack over a three-dimensional structure of a substrate by: forming a first electrode over the three-dimensional structure (e.g., using atomic layer deposition); forming a memory element over the first electrode (e.g., using atomic layer deposition); and forming a second electrode over the memory element (e.g., using atomic layer deposition), wherein the first electrode, the second electrode, and the memory element form a memory capacitor; and (i) wherein the substrate includes an oxide layer and wherein forming a first electrode includes (e.g., conformally) forming a first functional layer substantially consisting of a metal nitride or a metal-oxynitride directly on the oxide layer (e.g., using atomic layer deposition) and conformally forming a first electrically conductive electrode layer substantially consisting of a first metal (e.g., tungsten) directly on the first functional layer using atomic layer deposition, and/or (ii) wherein the memory element substantially consists of an oxide material (e.g., of one or more transition-metal-oxides) and wherein forming the second electrode includes (e.g., conformally) forming a second functional layer substantially consisting of a second metal nitride or a second metal-oxynitride over the memory element (e.g., using atomic layer deposition) and conformally forming a second electrically conductive electrode layer substantially consisting of a second metal (e.g., tungsten) directly on the second functional layer using atomic layer deposition.

In Example 146, the subject matter of Example 144 can optionally include that first electrically conductive electrode conformally covers the first functional layer and/or that the second electrically conductive electrode conformally covers the second functional layer.

In Example 147, the subject matter of Example 145 or 146 can optionally include that the three-dimensional structure has an aspect ratio equal to or greater than six (e.g., equal to or greater than ten, e.g., equal to or greater than fifteen, e.g., equal to or greater than twenty, etc.) and/or a width equal to or less than 200 nm (e.g., equal to or less than 100 nm, e.g., equal to or less than 50 nm, etc.).

In Example 148, the subject matter of any one of Examples 145 to 147 can optionally include that forming the first functional layer substantially consisting of the first metal nitride includes conformally forming the first functional layer by atomic layer deposition (e.g., using a nitrogen containing metalorganic precursor in combination with a reducing agent or using a halide precursor in combination with a nitridation agent); and/or wherein forming the second functional layer substantially consisting of the second metal nitride includes conformally forming the second functional layer by atomic layer deposition (e.g., using a nitrogen containing metalorganic precursor in combination with a reducing agent or using a halide precursor in combination with a nitridation agent).

In Example 149, the subject matter of any one of Examples 144 to 148 can optionally include that forming the first electrically conductive electrode layer includes conformally forming the first electrically conductive electrode layer by atomic layer deposition (e.g., using a metalorganic precursor in combination with one or more reducing agents or using a halide precursor); and/or wherein forming the second electrically conductive electrode layer includes conformally forming the second electrically conductive electrode layer by atomic layer deposition (e.g., using a metalorganic precursor in combination with one or more reducing agents or using a halide precursor).

In Example 150, the subject matter of Example 149 can optionally include that the halide precursor is tungsten fluoride.

In Example 151, the subject matter of any one of Examples 145 to 150 can optionally include that forming the first functional layer substantially consisting of the first metal-oxynitride and/or forming the second functional layer substantially consisting of the second metal-oxynitride includes: conformally forming a layer substantially consisting of a metal nitride using atomic layer deposition, the metal nitride including the metal of the metal-oxynitride; and oxidizing the metal nitride of the layer to thereby form the metal-oxynitride.

In Example 152, the method of any one of Examples 144 to 151 can optionally further include: etching the substrate to form a trench within the substrate as the three-dimensional structure.

In Example 153, the subject matter of any one of Examples 144 to 152 can optionally include that the three-dimensional structure includes at least one of a trench, a cup, a nanowire, nanoparticles, or a surface of a porous material.

Example 154 is a method including: forming an oxide layer; and forming an electrode layer substantially consisting of a metal directly on the oxide layer by: forming a layer substantially consisting of a metal nitride directly on the oxide layer, oxidizing the metal nitride of the layer such that the layer substantially consists of a metal oxide, and reducing the metal oxide of the layer to the metal to thereby form the electrode layer.

In Example 155, the subject matter of Example 154 can optionally include that the oxide layer substantially consists of one of: a metal oxide, a metalloid oxide, or one or more transition-metal-oxides.

Any of Examples 134 to 155 may be, where applicable, configured in accordance with one or more of the Examples 1 to 133.

Several aspects are described with reference to a structure (e.g., a memory transistor structure, a field-effect transistor based memory structure, such as a ferroelectric field-effect transistor based memory structure, a capacitor-based memory structure (e.g., including one or more capacitors), such as a 1C (one capacitor) memory cell or a 1C1T (one capacitor and one transistor) memory cell (wherein the transistor in a 1C1T memory cell is an access transistor) and it is noted that such a structure may include solely the respective element (e.g., a memory transistor, a field-effect transistor, a ferroelectric field-effect transistor, a capacitive memory); or, in other aspects, a structure may include the respective element and one or more additional elements.

The term “switch” may be used herein to describe a modification of the memory state a memory cell is residing in. For example, in the case that a memory cell is residing in a first memory state (e.g., the LVT state), the memory state the memory cell is residing in may be switched such that, after the switch, the memory cell may reside in a second memory state (e.g., the HVT state), different from the first memory state. The term “switch” may thus be used herein to describe a modification of the memory state a memory cell is residing in, from a first memory state to a second memory state. The term “switch” may also be used herein to describe a modification of a polarization, for example of a spontaneously-polarizable memory element (e.g., of a spontaneously-polarizable layer, such as a remanent-polarizable layer). For example, a polarization of a spontaneously-polarizable memory element may be switched, such that the sign of the polarization varies from positive to negative or from negative to positive, while the absolute value of the polarization may remain in some aspects substantially unaltered. According to various aspects, writing a memory cell may include bringing the memory cell from one of at least two memory states into another one of the at least two memory states of the memory cell (e.g., from the LVT state into the HVT state, or vice versa).

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., source-line node, bit-line node, and/or word-line node) of the memory cell may be understood as follows: the respective functional parts are electrically conductively connected to corresponding nodes and/or the respective functional parts itself provide the corresponding nodes. As an example, a source/drain node of a field-effect transistor memory structure may be electrically conductively connected to the source-line node of the memory cell or the source/drain node of the field-effect transistor memory structure may provide the source-line node of the memory cell. As another example, a source/drain node of the field-effect transistor memory structure may be electrically conductively connected to the bit-line node of the memory cell or the source/drain node of the field-effect transistor memory structure may provide the bit-line node of the memory cell.

The term “voltage” may be used herein with respect to “one or more bitline voltages”, “one or more wordline voltages”, “one or more plateline voltages”, “one or more sourceline voltages”, “one or more control line voltages”, “one or more base voltages” and the like. As an example, the term “base voltage” may be used herein to denote a reference voltage and/or a reference potential for the circuit. With respect to an electrical circuit, the base voltage may be also referred to as ground voltage, ground potential, virtual ground voltage, or zero volts (0 V). The base voltage of an electrical circuit may be defined by the power supply used to operate the electronic circuit. As another example, the term “control line voltage” may be used herein to denote a voltage that is provided to a control line, e.g., of a memory cell arrangement (for example a “wordline voltage” may be provided to a “wordline”, a “bitline voltage” may be provided to a bitline, a “sourceline voltage” may be provided to a sourceline, and a “plateline voltage” may be provided to a plateline). The sign of a voltage difference (e.g., a voltage drop) may be defined as a potential inside a memory cell (e.g., at a first electrode portion) minus a potential at a second electrode portion of the memory cell.

Illustratively, a voltage provided to a node or a terminal may assume any suitable value depending on the intended operation of the circuit including the node or terminal. For example, a bitline voltage (referred to as V_{BL} or VBL) may be varied depending on the intended operation of the memory cell arrangement. Analogously, a wordline voltage (referred to as V_{WL} or VWL), a plateline voltage (referred to as V_{PL} or VPL), and/or sourceline voltage (referred to as V_{SL} or VSL) may be varied depending on the intended operation of a memory cell arrangement. A voltage provided to a node or terminal may be defined by the respective potential applied to that node or terminal relative to the base voltage (referred to as V_{B}) of the circuit. Further, a voltage drop associated with two distinct nodes or terminals of a circuit may be defined by the respective voltages/potentials applied at the two nodes or terminals. As an example, a bitline voltage drop associated with a memory cell of a memory cell arrangement (e.g., an electrode of the memory cell) may be defined by the respective voltages/potentials applied at the corresponding memory cell (e.g., the electrode of the memory cell).

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The phrase “a current between” a first terminal or node and a second terminal or node may be used herein to mean a current from the first terminal or node to the second terminal or node as well as a current from the second terminal or node to the first terminal or node.

The phrase “a current through” a terminal, node, or region may be used herein to mean a current from the terminal or node to another terminal, another node, or another region as well as a current to the terminal, node, or region (e.g., from another terminal, another node, or another region).

A current may be detected using a current sense amplifier that outputs a voltage proportional to the current.

The phrase that a layer “substantially consists of” a material, as used herein, may be understood to mean that the layer may include other materials; however, a concentration of the other materials may be significantly lower than a concentration of the material. That the layer “substantially consists of” the material may be understood to mean that the layer includes at least 80 at. % (e.g., at least 90 at. %, e.g., at least 95 at. %, e.g., about 100 at. %) of the material or more (hence, the concentration of the material may be equal to or greater than 80 at. %). For example, a layer that substantially consists of hafnium oxide may consist of hafnium zirconium oxide, Hf₁₋ₓZrₓO₂, with 0.8≤x≤1. It may be understood that even in the case that a layer substantially consists of a specific material (e.g., zirconium oxide (ZrO₂), one or more other materials may diffuse from a neighboring layer into the layer such that the layer may include a small amount of atoms of the one or more other materials.

The phrase “substantially different”, as used herein, may be understood to mean that either the first concentration is substantially more than the second concentration or that the second concentration is substantially more than the first concentration. In the following, for illustrative purposes, the second concentration is described to be substantially more than the first concentration. However, it is understood that the first concentration may be substantially more than the second concentration in an analogous manner. The phrase that a second concentration of a second transition metal may be “substantially more” than a first concentration of a first transition metal (or vice versa) may be understood to mean that the second concentration of the second transition metal is at least 1.5-times the first concentration of the first transition metal. For example, the second concentration of the second transition metal may be at least twice the first concentration of the first transition metal. In an exemplary case that a layer includes hafnium zirconium oxide, Hf₁₋ₓZrₓO₂, the second concentration of the second transition metal, Hf, may be substantially more than the first concentration of the first transition metal, Zr, such that 0<x≤0.4. Hence, a concentration of the (second) oxide of the second transition metal (e.g., of HfO₂) may be equal to or greater than 60 at. % (e.g., equal to or greater than 55 at. %, e.g., equal to or greater than 70 at. %, e.g., equal to or greater than 75 at. %, etc.).

As used herein, a “concentration” of an element (e.g., of a transition metal) may refer to an atomic percentage (in at. %) of the element. Thus, in the case that the concentration of one element is compared to the concentration of another element, the atomic percentage of the one element may be compared to the atomic percentage of the other element. It is understood that a relation between the atomic percentage of the one element and the atomic percentage of the other element may directly refer to an atomic ratio between the one element and the other element. For example, in the case that the concentration (e.g., the atomic percentage) of the one element may be two times the concentration (e.g., the atomic percentage) of the other element, the atomic ratio between the one element and the other element may be 2 to 1 (2:1).

The term “metal” or “metal material” may be used herein to describe a metal (e.g., a pure or substantially pure metal) or a mixture of more than one metal, viz. a metal alloy. A “metal” may be an intermetallic material. Illustratively, the term “metal” may be used herein to describe a material having an electrical conductivity typical of a metal, for example an electrical conductivity greater than 106 S/m at a temperature of 20° C. The term “metal material” may be used herein to describe a material having the Fermi level inside at least one band. Therefore, in some aspects, the term “metal” may refer to a metalloid (also referred to as half-metal or semi-metal).

The terms “electrically conducting” or “electrically conductive” may be used herein interchangeably to describe a material or a layer having an electrical conductivity or an average electrical conductivity greater than 106 S/m at a temperature of 20° C. The term “electrically insulating” may be used herein interchangeably to describe a material or a layer having an electrical conductivity or an average electrical conductivity less than 10-10 S/m at a temperature of 20° C. In some aspects, a difference in electrical conductivity between an electrically conducting material (or layer) and an electrically insulating material (or layer) may have an absolute value of at least 1010 S/m at a temperature of 20° C., or of at least 1015 S/m at a temperature of 20° C.

The term “content” may be used herein, in some aspects, in relation to the “content of an element” in a material or in a layer to describe the mass percentage (or fraction) of that element over a total mass of the material (or of the layer). The term “content” may be used herein in relation to the “content of defects” in the structure of a material to describe the mass percentage of the defects over a total mass of the constituents of the structure. The term “content” may be used herein, in some aspects, in relation to the “content of an element” in a material or in a layer to describe the volume percentage of that element over a total volume of the material (or of the layer). The term “content” may be used herein in relation to the “content of defects” in the structure of a material to describe the volume percentage of the defects over a total volume of the structure.

The expression “a material of an element” or “a material of a layer”, for example “a material of a memory element”, or “a material of an electrode layer” may be used herein to describe a main component of that element or layer, e.g., a main material (for example, a main element or a main compound) present in that element or layer. The expression “a material of an element” or “a material of a layer” may describe, in some aspects, the material of that element or layer having a weight percentage greater than 60% over the total weight of the materials that the element or layer includes. The expression “a material of an element” or “a material of a layer” may describe, in some aspects, the material of that element or layer having a volume percentage greater than 60% over the total volume of the materials that the element or layer includes. As an example, a material of an element or layer including aluminum may describe that that element or layer is formed mostly by aluminum, and that other elements (e.g., impurities) may be present in a smaller proportion, e.g., having less weight percentage or less volume percentage compared to aluminum. As another example, a material of an element or layer including titanium nitride may describe that that element or layer is formed mostly by titanium nitride, and that other elements (e.g., impurities) may be present in a smaller proportion, e.g., having less weight percentage or less volume percentage compared to titanium nitride.

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.). In some aspects, the continuous region of a semiconductor portion may be provided by semiconductor material having only one dominant doping type.

The word “over”, used herein to describe forming a feature, e.g., a layer “over” a side or surface, may be used to mean that the feature, e.g., the layer, may be formed “directly on”, e.g., in direct contact with, the implied side or surface. The word “over”, used herein to describe forming a feature, e.g., a layer “over” a side or surface, may be used to mean that the feature, e.g., the layer, may be formed “indirectly on” the implied side or surface with one or more additional layers being arranged between the implied side or surface and the formed layer.

The term “lateral” used with regards to a lateral dimension (in other words a lateral extent) of a structure, a portion, a structure element, a layer, etc., provided, for example, over and/or in a carrier (e.g., a layer, a substrate, a wafer, etc.) or “laterally” next to, may be used herein to mean an extent or a positional relationship along a surface of the carrier. That means, in some aspects, that a surface of a carrier (e.g., a surface of a layer, a surface of a substrate, a surface of a wafer, etc.) may serve as reference, commonly referred to as the main processing surface. Further, the term “width” used with regards to a “width” of a structure, a portion, a structure element, a layer, etc., may be used herein to mean the lateral dimension (or in other words the lateral extent) of a structure. Further, the term “height” used with regards to a height of a structure, a portion, a structure element, a layer, etc., may be used herein to mean a dimension (in other words an extent) of a structure in a direction perpendicular to the surface of a carrier (e.g., perpendicular to the main processing surface of a carrier).

The term “thickness” used with regards to a “thickness” of a layer may be used herein to mean the dimension (in other words an extent) of the layer perpendicular to the surface of the support (the material or material structure) on which the layer is formed (e.g., deposited or grown). If a surface of the support is parallel to the surface of the carrier (e.g., parallel to the main processing surface) the “thickness” of the layer formed on the surface of the support may be the same as the height of the layer.

According to various aspects, various properties (e.g., physical properties, chemical properties, etc.) of a first component (e.g., elements, layers, structures, portions, etc.) and a second component may be compared to one another. It may be found that two or more components may be—with reference to a specific property-either equal to each other or different from one another. As a measure, a value that represents such a property may be either equal or not. In general, a skilled person may understand from the context of the application whether two values or properties are equal or not, e.g., usually, if values are in the range of a usual tolerance, they may be regarded equal. However, in some aspects or as long as not otherwise mentioned or understood, two values that differ from one another with at least 1% relative difference may be considered different from one another. Accordingly, two values that differ from one another with less than 1% relative difference may be considered equal to each other.

It may be understood, that the physical term “electrical conductivity” (also referred to as specific conductance, specific electrical conductance, as examples) may be defined as a material dependent property reciprocal to the physical term “electrical resistivity” (also referred to as specific electrical resistance, volume resistivity, as examples). Further properties of a layer or structure may be defined material dependent and the geometry dependent, e.g., by the physical terms “electrical resistance” and “electrical conductance”.

According to various aspects, the properties and/or the structure of the memory element, an electrode, an electrically conductive electrode layer, and/or a functional layer as described herein may be evaluated with techniques known in the art. As an example, transmission electron microscopy (TEM) may be used to determine the structure of an electrode, for example the presence of one or more electrode layers and/or the presence of one or more functional layers in the electrode. TEM may be used for identifying a layer, an interface, a crystal structure, a microstructure, and other properties. As another example, X-ray crystallography (X-ray diffraction) may be used to determine various properties of a layer or a material, such as the crystal structure, the lattice properties, the size and shape of a unit cell, the chemical composition, the phase or alteration of the phase, the presence of stress in the crystal structure, the microstructure, and the like. As a further example, energy-dispersive X-ray spectroscopy (EDS) may be used to determine the chemical composition of a layer or a material, e.g. the presence and/or the content of an element in the layer or material. As a further example, Rutherford backscattering spectrometry (RBS) may be used to determine the structure and/or the composition of a material. As a further example, secondary ion mass spectrometry (SIMS) may be used to analyze the molecular composition of the upper monolayers of a solid, e.g. for analyzing the spatial distribution (e.g., the gradient) of an element across the solid.

A composition of a layer, a concentration of one or more materials within the layer, a composition of a layer, and/or a concentration of one or more materials within the spontaneously polarizable memory element, etc. may be determined with techniques known in the art. For example, energy-dispersive X-ray spectroscopy (EDS) (e.g., in combination with scanning electron microcopy (SEM) or transmission electron microscopy (TEM)), Rutherford backscattering spectrometry (RBS), and/or secondary ion mass spectrometry (SIMS) may be used to analyze the composition and/or concentration. However, the composition of the layer, the concentration of the one or more materials within the layer, the composition of the spontaneously polarizable memory element, and/or the concentration of the one or more materials within the spontaneously polarizable memory element may be also apparent from a manufacturing protocol for manufacturing the respective layer. For example, a layer may be manufactured by means of deposition, such as atomic layer deposition (ALD) and the respective composition and/or concentration may be directly apparent from the used deposition protocol (e.g., the used ALD deposition protocol).

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase that an element or a group of elements “includes” another element or another group of elements may be used herein to mean that the other element or other group of elements may be part of the element or the group of elements or that the element or the group of elements may be configured or formed as the other element or the other group of elements (e.g., the element may be the other element).

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

An “electrically conductive” connection or coupling, as described herein, may include a direct electrical connection or an indirect electrical connection, wherein an indirect connection may include additional structures in the current path that have no influence on the substantial functioning of the described circuit or device.

It is noted that one or more functions described herein with reference to a memory cell, a memory cell arrangement, etc., may be accordingly part of a method, e.g., part of a method for operating a memory cell arrangement. Vice versa, one or more functions described herein with reference to a method, e.g., with reference to a method for operating a memory cell arrangement, may be implemented accordingly in a device or in a part of a device, for example, in a memory cell, a memory cell arrangement, etc.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory cell arrangement, comprising:
a substrate comprising a plurality of three-dimensional structures;
a plurality of memory cells; and
a plurality of sets of control lines for selectively addressing one or more memory cells of the plurality of memory cells;
wherein each memory cell of the plurality of memory cells comprises a memory layer stack a respective three-dimensional structure of the plurality of three-dimensional structures, the memory layer stack comprising:
a first electrode;
a memory element disposed over the first electrode, the memory element substantially consisting of one or more spontaneously polarizable transition-metal-oxides; and
a second electrode disposed over the memory element, wherein the first electrode, the second electrode, and the memory element form a memory capacitor;
wherein the substrate comprises an oxide layer at its interface to the memory layer stack and wherein the first electrode comprises a first electrically conductive electrode layer substantially consisting of tungsten and a first functional layer substantially consisting of a first metal nitride or a first metal-oxynitride, wherein the first electrically conductive electrode layer is disposed between the first functional layer and the memory element and wherein the first electrically conductive electrode layer is disposed in direct contact with the first functional layer; and
wherein the second electrode comprises a second electrically conductive electrode layer substantially consisting of tungsten and a second functional layer substantially consisting of a second metal nitride or a second metal-oxynitride, wherein the second functional layer is disposed between the memory element and the second electrically conductive electrode layer and wherein the second functional layer is disposed in direct contact with the memory element.

2. The memory cell according to claim 1,
wherein the respective three-dimensional structure comprises at least one of a trench, a cup, a nanowire, nanoparticles, or a surface of a porous material.

3. The memory cell according to claim 1,
wherein the first electrically conductive electrode conformally covers the first functional layer and/or wherein the second electrically conductive electrode conformally covers the second functional layer; and
wherein the respective three-dimensional structure has a width equal to or less than 200 nm and an aspect ratio equal to or greater than six.

4. The memory cell according to claim 1,
wherein the oxide layer substantially consists of a low-k material.

5. The memory cell according to claim 4,
wherein the respective three-dimensional structure is a trench disposed within the oxide layer or wherein the respective three-dimensional structure is a trench disposed within the substrate and conformally covered with one or more oxide layers.

6. The memory cell according to claim 1,
wherein the one or more transition-metal-oxides of the memory element are hafnium oxide, zirconium oxide, or hafnium zirconium oxide.

7. The memory cell according to claim 1,
wherein the first metal nitride and/or the second metal nitride is tungsten nitride; and/or
wherein the first metal-oxynitride and/or the second metal-oxynitride is tungsten-oxynitride.

8. The memory cell according to claim 1,
wherein the first functional layer and/or the second functional layer has a thickness greater than 1 nm.

9. The memory cell according to claim 1,
wherein the first metal nitride and/or the second metal nitride is one of: titanium nitride, tungsten nitride, molybdenum nitride, tantalum nitride, niobium nitride, hafnium nitride, or zirconium nitride.

10. The memory cell according to claim 1,
wherein the first electrode further comprises a further first functional layer substantially consisting of the first metal nitride or the first metal-oxynitride, wherein the further first functional layer is disposed between and in direct contact with the memory element and the first electrically conductive electrode layer; and/or
wherein the second electrode further comprises a further second functional layer substantially consisting of the second metal nitride or the second metal-oxynitride, wherein the further second functional layer is disposed directly on the second electrically conductive electrode layer.

11. A method, comprising:
forming a memory layer stack over a three-dimensional structure of a substrate by:
forming a first electrode over the three-dimensional structure;
forming a memory element over the first electrode using atomic layer deposition, the memory element substantially consisting of one or more transition-metal-oxides; and
forming a second electrode over the memory element, wherein the first electrode, the second electrode, and the memory element form a memory capacitor;
wherein the substrate comprises an oxide layer and wherein forming the first electrode comprises forming a first functional layer substantially consisting of a metal nitride or a metal-oxynitride directly on the oxide layer and conformally forming a first electrically conductive electrode layer substantially consisting of tungsten directly on the first functional layer using atomic layer deposition, and
wherein forming the second electrode comprises forming a second functional layer substantially consisting of a second metal nitride or a second metal-oxynitride over the memory element and conformally forming a second electrically conductive electrode layer substantially consisting of tungsten directly on the second functional layer using atomic layer deposition.

12. The method according to claim 11,
wherein the three-dimensional structure has a width equal to or less than 200 nm and an aspect ratio equal to or greater than six.

13. The method according to claim 11,
wherein forming the first functional layer substantially consisting of the first metal nitride comprises conformally forming the first functional layer by atomic layer deposition using a nitrogen containing metalorganic precursor in combination with a reducing agent or using a halide precursor in combination with a nitridation agent; and/or
wherein forming the second functional layer substantially consisting of the second metal nitride comprises conformally forming the second functional layer by atomic layer deposition using a nitrogen containing metalorganic precursor in combination with a reducing agent or using a halide precursor in combination with a nitridation agent.

14. The method according to claim 11,
wherein conformally forming the first electrically conductive electrode layer comprises conformally forming the first electrically conductive electrode layer by atomic layer deposition using a metalorganic precursor in combination with one or more reducing agents or using a halide precursor; and/or
wherein conformally forming the second electrically conductive electrode layer comprises conformally forming the second electrically conductive electrode layer by atomic layer deposition using a metalorganic precursor in combination with one or more reducing agents or using a halide precursor.

15. The method according to claim 14,
wherein the halide precursor is tungsten fluoride.

16. The method according to claim 11,
wherein forming the first functional layer substantially consisting of the first metal-oxynitride and/or forming the second functional layer substantially consisting of the second metal-oxynitride comprises:
conformally forming a layer substantially consisting of a metal nitride using atomic layer deposition, the metal nitride comprising the metal of the metal-oxynitride; and
oxidizing the metal nitride of the layer to thereby form the metal-oxynitride.

17. The method according to claim 11, further comprising:
etching the substrate to form a trench within the substrate as the three-dimensional structure.

18. The method according to claim 11,
wherein the three-dimensional structure comprises at least one of a trench, a cup, a nanowire, nanoparticles, or a surface of a porous material.

19. A method, comprising:
forming an oxide layer; and
forming an electrode layer substantially consisting of a metal directly on the oxide layer by:
forming a layer substantially consisting of a metal nitride directly on the oxide layer,
oxidizing the metal nitride of the layer such that the layer substantially consists of a metal oxide, and
reducing the metal oxide of the layer to the metal to thereby form the electrode layer.

20. The method according to claim 19,
wherein the oxide layer substantially consists of one of: a metal oxide, a metalloid oxide, or one or more transition-metal-oxides.
